(19) United States
(12) Patent Application Publication
(10) Pub. No.: US 2026/0090205 A1
(43) Pub. Date: Mar. 26, 2026

(54) DISPLAY DEVICE INCLUDING ORGANIC LIGHT EMITTING ELEMENT AND ELECTRONIC DEVICE INCLUDING THE DISPLAY DEVICE

(71) Applicant: Samsung Display Co., Ltd., Yongin-si (KR)

(72) Inventors: SANGHO JEON, Yongin-si (KR); MINSOO KIM, Yongin-si (KR); BEOMJIN KIM, Yongin-si (KR); SUNGJIN MUN, Yongin-si (KR); HYE JEONG PARK, Yongin-si (KR); JIHO SOHN, Yongin-si (KR); Eun Jeong HONG, Yongin-si (KR)

(21) Appl. No.: 19/221,220

(22) Filed: May 28, 2025

(30) Foreign Application Priority Data
Sep. 25, 2024 (KR) 10-2024-0129779

(51) Int. Cl. H10K 59/121; H10K 50/12; H10K 50/17; H10K 50/19

(52) U.S. Cl. CPC H10K 59/1213; H10K 50/12; H10K 50/17; H10K 50/19

(57) ABSTRACT

A display device and an electronic device including the display device are disclosed. The display device may include a red pixel, a green pixel, and a blue pixel, each including transistors and an organic light emitting element, wherein, with respect to the organic light emitting element, variance (ΔCap′ₘₐₓ) of capacitance at a maximum value of Equation 10 has a value of equal to or greater than 100%;

$$Δ {Cap}_{usx}^{′} ( c , T ) = \vert \frac{{Cap}_{max}^{′} ( c , T ) - {Cap}_{max} ( c , {T}_{0} )}{{Cap}_{max}^{′} ( c = Blue , T ) - {Cap}_{max} ( c = Blue , {T}_{0} )} \vert \times \frac{{Cap}_{max}^{′} ( c , T )}{{Cap}_{max} ( c , {T}_{0} )} / Δ {V}_{max} ( c , T ) \qquad Equation 10$$

variable c is a color, T is a temperature, To is 25° C., Cap is capacitance, ΔCap′ₘₐₓ(c, T) satisfies Equation 9,

$$Δ {Cap}_{max}^{′} ( c , T ) = Δ {Cap}_{max} ( c , T ) / Δ {V}_{max} ( c , T ) , \qquad Equation 9$$

variance (ΔCap(c, T)) of capacitance expressed based on a maximum value satisfies Equation 6,

$$Δ Cap ( c , T ) = \vert \frac{{Cap}_{max}^{′} ( c , T ) - {Cap}_{max} ( c , {T}_{0} )}{{Cap}_{max}^{′} ( c = Blue , T ) - {Cap}_{max} ( c = Blue , {T}_{0} )} \vert \times \frac{{Cap}_{max}^{′} ( c , T )}{{Cap}_{max} ( c , {T}_{0} )} , \qquad Equation 6$$

and variance (ΔVₘₐₓ) of a maximum voltage satisfies Equation 8.

$$Δ {V}_{max} ( c , T ) = {V}_{max} ( c , T ) / {V}_{max} ( c , {T}_{0} ) . \qquad Equation 8$$

### CROSS-REFERENCE TO RELATED APPLICATION

The present application claims priority to and the benefit of Korean Patent Application No. 10-2024-0129779, filed on Sep. 25, 2024, in the Korean Intellectual Property Office, the entire disclosure of which is incorporated herein by reference.

### BACKGROUND

### 1. Field

One or more embodiments of the present disclosure relate to a display device including an organic light emitting element and an electronic device including the display device.

### 2. Description of the Related Art

Display devices display images, and organic light emitting diode displays have been paid high attention.

The organic light emitting diode displays include an organic light emitting element and have self-emitting characteristics so they do not need an additional light source, which makes them different from the liquid crystal display devices, thereby reducing thickness and weight. The organic light emitting diode displays exhibit high-quality characteristics, such as low power consumption, high luminance, and high response speed.

The organic light emitting diode displays include a substrate, thin-film transistors on the substrate, insulation (e.g., electrical insulation) layers between wires that arrange the thin-film transistors, and an organic light emitting element to receive currents from the thin-film transistors. At least two thin-film transistors are used so that one organic light emitting element may emit light.

### SUMMARY

One or more aspects of embodiments of the present disclosure are directed toward a display device including an organic light emitting element of which luminance does not change depending on a temperature. One or more aspects of embodiments of the present disclosure are directed toward determining whether luminance changes depending on a temperature according to a test for an organic light emitting element.

Additional aspects of embodiments will be set forth in part in the description which follows and, in part, will be apparent from the description or may be learned by practice of the presented embodiments of the disclosure.

One or more embodiments of the present disclosure provides a display device including: a red pixel, a green pixel, and a blue pixel, each including transistors and an organic light emitting element, wherein, with respect to the organic light emitting element, variance (ΔCap′ₘₐₓ) of capacitance at a maximum value of Equation 10 has a value equal to or greater than 100%.

$$Equation 10$$

$$Δ {Cap}_{max}^{′} ( c , T ) = \vert \frac{{Cap}_{max}^{′} ( c , T ) \text{?} {Cap}_{max} ( c , {T}_{0} )}{{Cap}_{max}^{′} ( c = Blue , T ) \text{?} {Cap}_{max} ( c = Blue , {T}_{0} )} \vert \times \frac{{Cap}_{max}^{′} ( c , T )}{{Cap}_{max} ( c , {T}_{0} )} / Δ {V}_{max} ( c , T )$$

$$\text{?} \text{indicates text missing or illegible when filed}$$

where variable c is a color, T is a temperature, To is 25° C., Cap is capacitance, and ΔCap′ₘₐₓ(c,T) satisfies Equation 9,

$$Δ {Cap}_{max}^{′} ( c , T ) = Δ {Cap}_{max} ( c , T ) / Δ {V}_{max} ( c , T ) , \qquad Equation 9$$

variance (ΔCap(c,T)) of capacitance expressed based on a maximum value satisfies Equation 6,

$$\vert \frac{{Cap}_{max}^{′} ( c , T ) - {Cap}_{max} ( c , {T}_{0} )}{{Cap}_{max}^{′} ( c = Blue , T ) - {Cap}_{max} ( c = Blue , {T}_{0} )} \vert \times \frac{{Cap}_{max}^{′} ( c , T )}{{Cap}_{max} ( c , {T}_{0} )} , \qquad Equation 6$$

and
variance (ΔVₘₐₓ) of a maximum voltage satisfies Equation 8.

$${V}_{max} ( c , T ) / \text{?} ( c , {T}_{0} ) . \qquad Equation 8$$

$$\text{?} \text{indicates text missing or illegible when filed}$$

The variance (ΔCap′ₘₐₓ) of capacitance at the maximum value may have values for red and green that are equal to or greater than 500%.

An entire voltage range of a driving voltage applied to the organic light emitting element may have the value equal to or greater than −1 V and equal to or less than 10 V.

An organic layer of the organic light emitting element may have a difference between electron mobility and hole mobility that is equal to or greater than 1 e⁻⁹ cm²/Vs and equal to or less than 1 e⁻³ cm²/Vs.

An interface barrier value at a border between adjacent layers in the organic light emitting element may have the value of equal to or greater than −0.3 Ev and equal to or less than 0.5 Ev.

The organic light emitting element may include a p-doping hole injection layer, and doping concentration of the p-doping hole injection layer may be equal to or greater than 0.1% and equal to or less than 5%.

The organic light emitting element may include a hole transport layer and a light emitting layer, and may further include at least one auxiliary layer between the hole transport layer and the light emitting layer.

The organic light emitting element may have a tandem structure including light emitting layers and charge generating layers.

The charge generating layer (e.g., each of the charge generating layers) may be an n-charge generating layer or a p-charge generating layer, and the n-charge generating layer or the p-charge generating layer may have the value equal to or greater than 0.1 Ev and equal to or less than 3.0 Ev as an interface barrier value.

Doping of the n-charge generating layer and/or the p-charge generating layer is performed at a lower concentration on a border portion than at an intermediate portion of the corresponding layer. In one or more embodiments, a border portion of the n-charge generating layer and/or the p-charge generating layer is doped at a lower concentration than at an intermediate portion of the corresponding layer.

An energy disorder value of an organic layer in the organic light emitting element may have the value of equal to or greater than 0.1 Ev.

The organic light emitting element may have the value of a temperature sensitivity factor (TSF) of Equation 3 equal to or greater than 0.15×10⁻¹ Cd·m²/V and equal to or less than 0.7×10⁻¹ Cd·m²/V.

$$TSF = \frac{d ( \frac{Δ L ( c , T )}{Δ J ( c , T )} )}{dV ( c )} \qquad Equation 3$$

Herein, ΔJ is variance of current density, ΔL is luminance variance, V is voltage, variable c is color, and T is temperature.

The organic light emitting element may be doped with a dopant of iridium or platinum.

The organic light emitting element may include at least two layers selected from among a hole injection layer, a p-doping hole injection layer, a hole transport layer, a light emitting layer, a dopant (e.g., a dopant layer), a buffer layer, an electron transport layer, and an auxiliary layer, the respective layers (e.g., each of the at least two layers) of the organic light emitting element may be doped with the dopant of iridium or platinum, and an average of the dipole moment values of the layers that exclude the dopant selected from among each of the layers (e.g., each of the at least two layers) of the organic light emitting element may be equal to or greater than 2 debye.

The display device may be included in an electronic device such as a mobile phone, a TV, a monitor, a laptop, and/or a vehicle.

One or more embodiments of the present disclosure provides a display device including: a red pixel, a green pixel, and a blue pixel, each including transistors and an organic light emitting element, wherein, with respect to the organic light emitting element, a value of a temperature sensitivity factor (TSF) is equal to or greater than 0.15×10⁻¹ Cd·m²/V and equal to or less than 0.25×10⁻¹ Cd·m²/V or is equal to or greater than 0.51×10⁻¹ Cd·m²/V and equal to or less than 0.7×10⁻¹ Cd·m²/V as in Equation 3.

$$TSF = \frac{d ( \frac{Δ L ( c , T )}{Δ J ( c , T )} )}{dV ( c )} \qquad Equation 3$$

Herein, ΔJ is variance of current density, ΔL is luminance variance, V is voltage, variable c is color, and T is temperature.

Variance (maximum ΔJ) of maximum current density at a low grayscale has a range of 380±60%, and variance (minimum ΔJ) of minimum current density at a high grayscale has a range of 170±30%.

A ratio (ΔL/ΔJ) value of variance (ΔJ) of minimum current density at the low grayscale and variance (ΔL) of luminance may have the range of 30±10%, and the ratio (ΔL/ΔJ) value of the variance (ΔJ) of maximum current density and the variance (ΔL) of luminance at the high grayscale may have the range of 55±10%.

The low grayscale may be equal to or less than a 23^{rd} grayscale, and the high grayscale may be greater than the 23^{rd} grayscale.

A difference between a value of an initial voltage on one side in a range of voltage applied to the organic light emitting element and the variance (ΔJ) of current density or a saturation voltage at which the ratio (ΔL/ΔJ) of the variance (ΔJ) of current density and the variance (ΔL) of luminance starts being saturated may be equal to or greater than 0.3 V.

The Initial voltage may have the value of equal to or greater than −1 V and equal to or less than 6 V, and the saturation voltage may have the value of equal to or greater than 1.3 V and equal to or less than 10 V.

An entire voltage range of a driving voltage applied to the organic light emitting element may have the value of equal to or greater than −1 V and equal to or less than 10 V.

An organic layer of the organic light emitting element may have a difference between electron mobility and hole mobility that is equal to or greater than 1 e⁻⁹ cm²/Vs and equal to or less than 1 e⁻³ cm²/Vs.

An interface barrier value at a border between adjacent layers in the organic light emitting element may have the value of equal to or greater than −0.3 Ev and equal to or less than 0.5 Ev.

The organic light emitting element may include a p-doping hole injection layer, and doping concentration of the p-doping hole injection layer may be equal to or greater than 0.1% and equal to or less than 5%.

The organic light emitting element may include a hole transport layer and a light emitting layer, and may further include at least one auxiliary layer between the hole transport layer and the light emitting layer.

The organic light emitting element may have a tandem structure including light emitting layers and charge generating layers.

The charge generating layer (e.g., each of the charge generating layers) may be an n-charge generating layer or a p-charge generating layer, and the n-charge generating layer or the p-charge generating layer may have the value of equal to or greater than 0.1 Ev and equal to or less than 3.0 Ev as an interface barrier value.

Doping of the n-charge generating layer and/or the p-charge generating layer may be performed on a border portion of the corresponding layer at lower concentration than an intermediate portion of the corresponding layer. In one or more embodiments, a border portion of the n-charge generating layer and/or the p-charge generating layer may be doped at a lower concentration than an intermediate portion of corresponding layer.

An energy disorder value of an organic layer in the organic light emitting element may have the value of equal to or greater than 0.1 Ev.

With respect to the organic light emitting element, the variance (ΔCap′ₘₐₓ) of capacitance at the maximum value of Equation 10 may have the value of equal to or greater than 100%.

$$Equation 10$$

$$Δ {Cap}_{max}^{′} ( c , T ) = \vert \frac{{Cap}_{max}^{′} ( c , T ) \text{?} {Cap}_{max} ( c , {T}_{0} )}{{Cap}_{max}^{′} ( c = Blue , T ) \text{?} {Cap}_{max} ( c = Blue , {T}_{0} )} \vert \times \frac{{Cap}_{max}^{′} ( c , T )}{{Cap}_{max} ( c , {T}_{0} )} / Δ {V}_{max} ( c , T )$$

$$\text{?} \text{indicates text missing or illegible when filed}$$

Herein, variable c is color, T is temperature, To is 25° C., and Cap is capacitance, and ΔCap′ₘₐₓ(c, T) may satisfy Equation 9.

$$Δ {Cap}_{max}^{′} ( c , T ) = Δ {Cap}_{max} ( c , T ) / Δ {V}_{max} ( c , T ) , \qquad Equation 9$$

Herein, the variance (ΔCap(c, T)) of capacitance expressed based on the maximum value may satisfy Equation 6.

$$\vert \frac{{Cap}_{max}^{′} ( c , T ) - {Cap}_{max} ( c , {T}_{0} )}{{Cap}_{max}^{′} ( c = Blue , T ) - {Cap}_{max} ( c = Blue , {T}_{0} )} \vert \times \frac{{Cap}_{max}^{′} ( c , T )}{{Cap}_{max} ( c , {T}_{0} )} \text{?} \qquad Equation 6$$

$$\text{?} \text{indicates text missing or illegible when filed}$$

The variance (ΔVₘₐₓ) of the maximum voltage may satisfy Equation 8.

$${V}_{max} ( c , T ) / {V}_{max} ( c , {T}_{0} ) . \qquad Equation 8$$

The variance (ΔCap′ₘₐₓ) of capacitance at the maximum value may have the value for red and the value for green that are equal to or greater than 500%.

The organic light emitting element may be doped with a dopant of iridium or platinum.

The organic light emitting element may include at least two layers selected from among a hole injection layer, a p-doping hole injection layer, a hole transport layer, a light emitting layer, a dopant (e.g., a dopant layer), a buffer layer, an electron transport layer, and an auxiliary layer, the respective layers (e.g., each of the at least two layers) of the organic light emitting element may be doped with the dopant of iridium or platinum, and an average of dipole moment values of the layers that exclude the dopant selected from among each of the layers (e.g., each of the at least two layers) of the organic light emitting element may be equal to or greater than 2 debye.

The display device may be included in an electronic device such as a mobile phone, a TV, a monitor, a laptop, and a vehicle.

According to the embodiments, the display device including an organic light emitting element for preventing or reducing sensitive changes of luminance according to temperature changes may be formed by allowing the organic light emitting element to check whether luminance sensitivity changes with respect to the temperature based on a test of the organic light emitting element. According to the embodiments, the display device with low temperature sensitivity may be provided by checking temperature sensitivity of the organic light emitting element based on the measurement value measured through the test elements group (TEG).

According to one or more embodiments, an electronic device includes the display device as described in one or more embodiments.

The electronic device may be a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IoT) device, a smartwatch, a watch phone, and/or a head-mounted display (HMD).

### BRIEF DESCRIPTION OF THE DRAWINGS

The accompanying drawings, together with the specification, illustrate embodiments of the subject matter of the present disclosure, and, together with the description, serve to explain principles of embodiments of the subject matter of the present disclosure.

FIG. 1 is a top plan view of a display device according to one or more embodiments.

FIG. 2 is an equivalent circuit diagram of a pixel included in a display device according to one or more embodiments.

FIG. 3 is a cross-sectional view of a test element of a display device according to one or more embodiments.

FIG. 4 is a table that provides definitions of the abbreviations and acronyms used in the present disclosure.

FIGS. 5-14 illustrate the meanings of expressions that correspond to temperature sensitivity of an organic light emitting element according to one or more embodiments.

FIG. 15 is a graph of a result of measuring temperature sensitivity factors (TSF) of an organic light emitting element.

FIGS. 16-20 are graphs of variance of capacitance.

FIG. 21 is a cross-sectional view of an organic light emitting element in a tandem structure.

FIGS. 22-26 are graphs of characteristics of an organic light emitting element in a tandem structure.

FIGS. 27-30 illustrate energy levels of a portion of an organic light emitting element in a tandem structure according to one or more embodiments.

FIGS. 31A-32B are graphs of changes according to an additional doping of iridium.

FIG. 33 is the number of elements that correspond to the actual measured values (TLS) of luminance variance for one or more organic light emitting elements.

FIG. 34 is a table of energy levels of the respective layers of an organic light emitting element according to one or more embodiments.

FIG. 35 is a table of conditions based on the characteristics of an organic light emitting element according to one or more embodiments.

### DETAILED DESCRIPTION

The subject matter of the present disclosure will be described more fully hereinafter with reference to the accompanying drawings, in which embodiments of the present disclosure are shown. As those skilled in the art would realize, the described embodiments may be modified in one or more suitable different ways, all without departing from the spirit or scope of the present disclosure. The drawings and description are to be regarded as illustrative in nature and not restrictive. Like reference numerals designate like elements throughout the attached drawings and the written description, and duplicative descriptions thereof may not be provided in the specification.

As used herein, the singular forms “a,” “an,” and “the” are intended to include the plural forms as well, unless the context clearly indicates otherwise.

The singular forms as used herein are intended to include the plural forms as well unless the context clearly indicates otherwise.

The term “and/or” shall include the combination of a plurality of listed items or any of the plurality of listed items.

The use of “may” if (e.g., when) describing embodiments of the present disclosure refers to “one or more embodiments of the present disclosure.”

As used herein, the terms “use,” “using,” and “used” may be considered synonymous with the terms “utilize,” “utilizing,” and “utilized,” respectively.

Parts that are irrelevant to the description may not be provided to clearly describe the present disclosure, and substantially the same elements will be designated by the same reference numerals throughout the specification.

The size and thickness of each configuration or arrangement shown in the drawings may be arbitrarily shown for better understanding and ease of description, but embodiments of the present disclosure are not limited thereto. The thicknesses of layers, films, panels, regions, and/or the like may be enlarged for clarity. The thicknesses of one or more layers and areas may be exaggerated to effectively or suitably illustrate the technical contents of the present disclosure.

It should be understood that if (e.g., when) an element, such as a layer, a film, a region, or a substrate, is referred to as being “on” another element, it may be directly on the other element or intervening elements may also be present therebetween. In contrast, if (e.g., when) an element is referred to as being “directly on” another element, there are no intervening elements present therebetween.

The word “on” or “above” refers to as being on or below the object portion, and does not necessarily refer to as being on the upper side of the object portion based on a gravitational direction.

It will be understood that, although the terms “first,” “second,” “third,” and/or the like may be used herein to describe one or more elements, components, regions, layers, and/or sections, these elements, components, regions, layers, and/or sections should not be limited by these terms. These terms are used to distinguish one element, component, region, layer, or section from another element, component, region, layer, or section. Thus, a first element, a first component, a first region, a first layer, or a first section as described herein may be termed a second element, a second component, a second region, a second layer, or a second section, without departing from the spirit and scope of the present disclosure.

It will be further understood that the terms “has,” “having,” “comprises,” and/or “comprising” used herein specify the presence of stated features or components, but do not preclude the presence or addition of one or more other features or components. For example, it should be understood that the term “comprise(s)/comprising,” “include(s)/including,” or “have/has/having” specifies the presence of stated features, integers, steps, operations, elements, and/or components, but do not preclude the presence or addition of one or more other features, integers, steps, operations, elements, components, and/or groups thereof. Additionally, the terms “comprise(s)/comprising,” “include(s)/including,” “have/has/having” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in the present disclosure is intended to include all higher numerical limitations subsumed therein. Accordingly, Applicant reserves the right to amend this specification, including the claims, to expressly recite any sub-range subsumed within the ranges expressly recited herein.

As used herein, the terms “substantially,” “about,” and similar terms are used as terms of approximation and not as terms of degree and are intended to account for the inherent deviations in measured or calculated values that would be recognized by those of ordinary skill in the art.

As utilized herein, the term “about” or similar terms are used as terms of approximation and not as terms of degree and are intended to account for the inherent deviations in measured or calculated values that would be recognized by those of ordinary skill in the art. The term “about” or “approximately,” as used herein, is also inclusive of the stated value and refers to within an acceptable range of deviation for the particular value as determined by one of ordinary skill in the art, considering the measurement in question and the error associated with measurement of the particular quantity (e.g., the limitations of the measurement system). For example, “about” may refer to within one or more standard deviations, or within ±30%, ±20%, ±10%, or ±5% of the stated value.

The phrase “in a plan view” refers to viewing an object portion from the top, and the phrase “in a cross-sectional view” refers to viewing a cross-section of which the object portion is vertically cut from the side.

Throughout the specification, if (e.g., when) it is stated that a part is “connected” to another part, the part may be directly connected to the other part, may be connected to the other part through a third part, or may be connected to the other part physically or electrically, and they may be referred to by different titles depending on positions or functions, but the portions that are substantially integrated into one body may be connected to each other.

If (e.g., when) parts, such as wires, layers, films, regions, plates, or constituent elements, are said to extend in the “first direction or the second direction,” this not only signifies a straight-line shape that runs straight in a corresponding direction, but also includes a structure that generally extends in the first direction or the second direction, a structure bent on a set or predetermined portion, a zigzag-shaped structure, or a structure including a curved structure.

Electronic devices (e.g., mobile phones, TVs, monitors, laptop computers, and/or the like) including the display device and the display panel as described in one or more embodiments of the present disclosure or the electronic devices including the display device and the display panel manufactured by a manufacturing method as described in one or more embodiments of the present disclosure are not excluded from the claimed range of the present disclosure.

Unless otherwise defined, all terms, including technical terms and scientific terms, used herein have substantially the same meaning as how they are generally understood by those of ordinary skill in the art to which the present disclosure pertains. Any term that is defined in a general dictionary shall be construed to have substantially the same meaning in the context of the relevant art and, unless otherwise defined explicitly, shall not be interpreted to have an idealistic or excessively formalistic meaning.

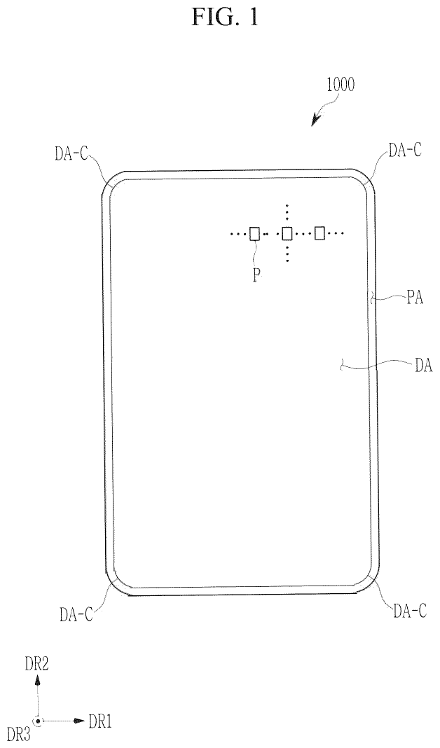

A schematic structure of a display device according to one or more embodiments will be described herein in more detail with reference to FIG. 1.

FIG. 1 is a top plan view of a display device according to one or more embodiments.

Referring to FIG. 1, the display device 1000 may include a display area DA in which pixels P are arranged or provided and which displays images, and a non-display area PA provided near the display area DA. The non-display area PA may display no images.

The display area DA may, for example, have a quadrangular shape (e.g., a substantially quadrangular shape), and as shown in FIG. 1, each corner DA-C of the display area DA may have a round shape (e.g., a substantially round shape), depending on one or more embodiments. The non-display area PA may have a shape around (e.g., surrounding) the display area DA. However, without being limited thereto, the display area DA and the non-display area PA may have one or more suitable shapes.

The display area DA may include pixels P and display images. The pixels P may include transistors, capacitors, and organic light emitting elements.

The non-display area PA may be around (e.g., surround) the display area DA. The non-display area PA may display no images and may be on an external portion of the display device 1000. At least a portion of the display device 1000 may be a flexible display device including a bending portion. For example, the display device 1000 may have a flat (e.g., substantially flat) center portion and a bent edge portion. At least a portion of the display area DA may be on the bending portion, so that at least a portion of the display area DA may have a bent shape (e.g., a substantially bent shape). A test element formed or provided by a substantially same process as the organic light emitting element of the pixels P may be formed or provided in the non-display area PA.

With respect to the display device 1000, a surface to display images may be parallel (e.g., substantially parallel) to a surface defined by a first direction DR1 and a second direction DR2. A normal direction of the surface to display images, for example, a thickness direction of the display device 1000, may be indicated by a third direction DR3. The front surfaces (or the upper surfaces) and the rear surfaces (or the lower surfaces) of respective members may be divided by the third direction DR3. The directions indicated by the first direction DR1, the second direction DR2, and the third direction DR3 may be relative concepts and may be converted into other directions.

The display device 1000 may further include a touch unit and/or a cover window on an upper side.

The display device 1000 may be a flat (e.g., substantially flat) rigid display device, or without being limited thereto, it may be a flexible display device. The display device may include a color converting layer including quantum dots and/or a color filter.

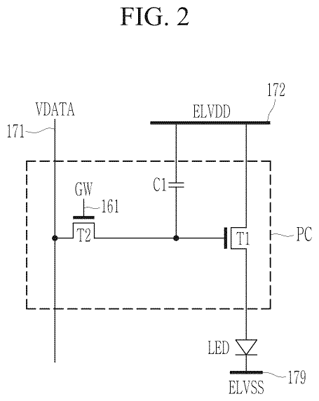

A basic circuit structure of the pixel P in the display area DA will be described herein in more detail with reference to FIG. 2.

FIG. 2 is an equivalent circuit diagram on a pixel included in a display device according to one or more embodiments.

The pixel as shown in FIG. 2 includes two transistors T1 and T2, a capacitor C1, and an organic light emitting element LED.

With respect to a structure of FIG. 2, one pixel may include an organic light emitting element LED and a pixel driver PC to drive the organic light emitting element LED. The pixel driver may include all the elements excluding the organic light emitting element LED in FIG. 2, and the pixel driver of the pixel according to FIG. 2 may include a first transistor T1, a second transistor T2, and a first capacitor C1.

The pixel driver may be connected to a first scan line 161 to apply a first scan signal GW and a data line 171 to apply a data voltage VDATA. The pixel may be connected to a first driving voltage line 172 to apply a driving voltage ELVDD (or a first driving voltage) and a second driving voltage line 179 to apply a driving low voltage ELVSS (or a second driving voltage).

A circuit structure of the pixel will be described herein in more detail focusing on the respective elements (e.g., transistors, capacitors, and organic light emitting elements) included in the pixel.

The first transistor T1 (or a driving transistor) may include a gate electrode connected to a first electrode of a first capacitor C1 and a second electrode of a second transistor T2, a first electrode (e.g., an input-side electrode) connected to the first driving voltage line 172, and a second electrode (e.g., an output-side electrode) connected to an anode of the organic light emitting element LED.

With respect to the first transistor T1, a turn-on degree of the first transistor T1 may be determined according to the voltage at the gate electrode, and a size of a current that flows to the second electrode from the first electrode of the first transistor T1 may be determined according to the turn-on degree. The current that flows to the second electrode from the first electrode of the first transistor T1 may be transmitted to the anode of the organic light emitting element LED, and it may be referred to as a light emitting current. The first transistor T1 may be of a negative type or kind transistor (e.g., an n-type transistor), and the greater the voltage at gate electrode is, the larger the light emitting current may flow. If (e.g., when) the light emitting current is large, the organic light emitting element LED may display high luminance.

The second transistor T2 (or a data input transistor) may include a gate electrode connected to the first scan line 161 to apply the first scan signal GW, a first electrode (e.g., an input-side electrode) connected to the data line 171 to apply the data voltage VDATA, and a second electrode (e.g., an output-side electrode) connected to the first electrode of the first capacitor C1 and the gate electrode of the first transistor T1. The second transistor T2 may input the data voltage VDATA to the pixel according to the first scan signal GW to transmit the data voltage VDATA to the gate electrode of the first transistor T1 and store the data voltage VDATA in the first electrode of the first capacitor C1.

All the transistors may be of n-type transistors, they may be turned on if (e.g., when) the voltages at the gate electrodes are high-level voltages, and they may be turned off if (e.g., when) the voltages at the gate electrodes are low-level voltages. The semiconductor layers included in the respective transistors may use polycrystalline silicon semiconductors and/or oxide semiconductors, and may additionally use amorphous (e.g., non-crystalline) semiconductors and/or monocrystalline semiconductors.

According to one or more embodiments, the semiconductor layers included in each of the transistors may further include an overlapping layer (or an additional gate electrode) that overlaps the semiconductor layer, and may apply a voltage to the overlapping layer (or the additional gate electrode) to change the characteristics of the transistors, and further improve or enhance display quality of the pixels.

The first capacitor C1 may include a first electrode connected to the gate electrode of the first transistor T1 and a second electrode of the second transistor T2 and a second electrode to receive the first driving voltage ELVDD. The first electrode of the first capacitor C1 may receive the data voltage VDATA from the second transistor T2 and stores the data voltage VDATA.

The organic light emitting element LED may include a cathode connected to the second driving voltage line 179 to receive a second driving voltage ELVSS, and an anode connected to the second electrode of the first transistor T1. The organic light emitting element LED may be between the pixel driver and the second driving voltage ELVSS, substantially the same current as the current that flows to the first transistor T1 of the pixel driver, and light emitting luminance may be determined according to the size of the corresponding current. The organic light emitting element LED may include a light emitting layer on which an organic light emitting material is between the anode and the cathode. A hole injection layer and/or a hole transport layer may be further provided between the anode and the light emitting layer, and an electron transport layer and/or electron injection layer may be further provided between the cathode and the light emitting layer.

FIG. 2 illustrates that the single pixel P may include two transistors T1 and T2 and one capacitor (or the first capacitor C1), which is not limited thereto, and the pixel P may further include capacitors or transistors depending on one or more embodiments. Depending on one or more embodiments, the transistor may be of a positive type or kind transistor (e.g., a p-type transistor). Further, the pixel according to one or more embodiments may include two transistors, one capacitor, and the organic light emitting element, and its connection relationship may be different from that of FIG. 2.

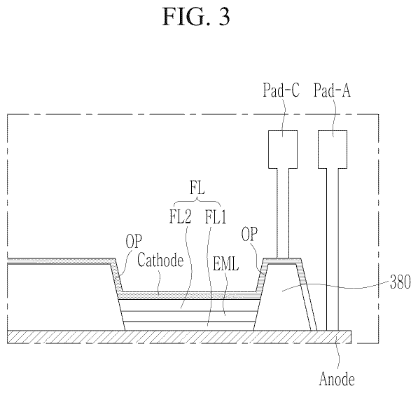

A cross-sectional structure of a test element formed or provided by substantially the same process as the organic light emitting element LED of the pixel in the display area DA and formed or provided in the non-display area PA for the purpose of tests will be described herein in more detail with reference to FIG. 3.

FIG. 3 is a cross-sectional view on a test element of a display device according to one or more embodiments.

The test element as shown in FIG. 3 may be generated by substantially the same material and substantially the same process as the stacking structure of the organic light emitting element of the pixel in the display area DA, and it may have substantially the same stacking structure.

A stacking structure of the test element will be described herein in more detail with reference to FIG. 3.

The anode may be on an organic film.

The anode may be made of a single layer including a transparent (e.g., substantially transparent) conductive (e.g., electrically conductive) oxide layer or a metallic material or a multilayer including the transparent conductive oxide layer and/or the metallic material. The transparent (e.g., substantially transparent) conductive (e.g., electrically conductive) oxide layer may include indium tin oxide (ITO), poly-ITO, indium zinc oxide (IZO), indium gallium zinc oxide (IGZO), and/or indium tin zinc oxide (ITZO). The metallic material may include silver (Ag), molybdenum (Mo), copper (Cu), gold (Au), and/or aluminum (Al).

A pixel defining layer 380 including an opening OP may be on the anode.

The opening OP (or a light emitting element opening) of the pixel defining layer 380 may correspond to the organic light emitting element in a plan view, and the light emitting layer EML may be formed or provided inside.

A first function layer FL1 may be between the anode and the light emitting layer EML, and a second function layer FL2 may be between the cathode and the light emitting layer EML. The first function layer FL1 may include the hole injection layer and/or the hole transport layer, and the second function layer FL2 may include the electron transport layer and/or the electron injection layer. The function layer FL and the light emitting layer EML may configure or provide an intermediate layer. Depending on one or more embodiments, the first function layer FL1 and the second function layer FL2 may be on the pixel defining layer 380.

The cathode may be on the second function layer FL2 and also on the pixel defining layer 380 and the opening OP.

The cathode may be of a transparent (e.g., substantially transparent) conductive (e.g., electrically conductive) layer including indium tin oxide (ITO), indium zinc oxide (IZO), indium gallium zinc oxide (IGZO), and/or indium tin zinc oxide (ITZO). The cathode may have a semi-transparent characteristic.

A plurality of test elements may be in the non-display area PA, and the cross-sectional structure of the test element may have substantially the same stacking structure as the organic light emitting element in the display area DA.

The organic light emitting element in the display area DA may include the anode, the light emitting layer EML, and the cathode, and may further include the first function layer FL1 and the second function layer FL2.

A transistor and a capacitor may be on a lower portion of the organic film in the display area DA, and the transistor may be electrically connected to the anode in the display area DA. As a result, the anode may receive the current from the transistor on a lower portion of the organic film in the display area DA, and the current transmitted to the anode may pass through the first function layer FL1, the light emitting layer EML, and the second function layer FL2 and may be transmitted to the cathode. The light emitting layer EML may emit light because of the current that flows to the light emitting layer EML, and the organic light emitting element may provide luminance.

As the organic light emitting element in the display area DA is formed or provided with substantially the same material and substantially the same process, the test element in the non-display area PA as shown in FIG. 3 may have substantially the same characteristic. As a result, a testing result obtained by applying a current voltage to the test element in the non-display area PA may correspond to the characteristics of the organic light emitting element in the display area DA.

Therefore, it may be checked to determine whether the changes of luminance, the changes of gamma, and the changes of colors are less generated to the organic light emitting element in the display area DA with respect to temperature by testing the test element in the non-display area PA. For example, if (e.g., when) the display luminance, the gamma, and the colors change according to the temperature used by the display device, displaying quality may not be constant (e.g., substantially constant). Therefore, in the following, the resultant values measured from the test element may be used to form or provide the display device having low sensitivity to temperature and may not degrade display quality if (e.g., when) certain (e.g., set or predetermined) conditions are met.

Depending on one or more embodiments, to check the characteristics of the light emitting layer, the organic light emitting element may be stacked and formed or provided and the test may be performed, apart from the display device.

Referring to FIG. 3, a pad A (Pad-A) may be connected to an anode of the test element, and a pad C (Pad-C) may be connected to the cathode.

For example, voltages and currents may be supplied to the pads Pad-A and Pad-C to test the test element in the non-display area PA, and the corresponding values, such as currents, voltages, and/or capacitance, may be measured, luminance of light emitted by the light emitting layer EML may be measured, and it may be determined whether they are within a set or predetermined condition using the measured currents, voltages, capacitance, and/or luminance, thereby determining whether sensitivity to temperature is reduced. The values to be measured by the test element may be divided into two groups, and the groups may be measured by a separate test. A first measurement group may include luminance, currents (or current density), and voltages to correspond to a J-V-L characteristic test, and a second measurement group may include capacitance and voltages to correspond to a C-V characteristic test.

An expected value (TEGΔL(c, T, G)) of luminance variance expressed in Equation 1 may be found using each of the values calculated by the test element according to one or more embodiments.

$$Equation 1$$

$$TEG Δ L ( c , T , G ) = ( 1 + \frac{d ( \frac{Δ L ( c , T )}{Δ J ( c , T )} )}{dV ( c )} \times \frac{1}{a} \frac{J ( c , {G}_{0} )}{J ( c , G )} \times Op . V ( c , G ) \times ( Δ J ( c , T , G ) \times LL ) ) \times 100$$

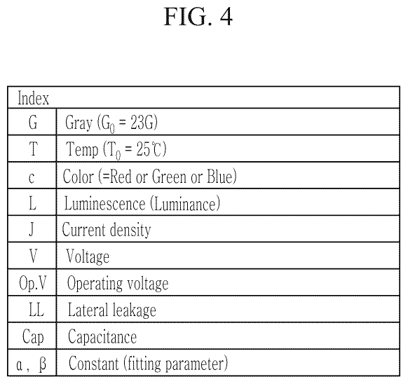

The abbreviations and acronyms used in Equation 1 are described in more detail in FIG. 4.

FIG. 4 is a table that provides definitions of the abbreviations and acronyms used in the present disclosure.

Referring to FIG. 4, grayscale (G), temperature (T) (or Temp.), color (c) (e.g., red, green, or blue), luminance (L) (or luminescence), current density (J), voltage (V), operating voltage (Op.V), a factor that corresponds to lateral leakage (LL) (or a lateral leakage factor; see Equation 5), capacitance (Cap), and constants (α and β) are written in abbreviations and acronyms. From among the abbreviations and acronyms, grayscale (G), temperature (T), and color (c) may be used as variables, and the luminance (L), current density (J), voltage (V), and operating voltage (Op.V) may be functions that use at least one variable selected from among grayscale (G), temperature (T), and color (c). A reference grayscale (Go) may use 23 grayscales selected from among 64 grayscales of 0 to 63, and a reference temperature (T₀) may use 25° C., which is a room temperature. The color may be one selected from among red, green, and blue, and the current density (J) may correspond to the operating voltage (Op.V). The temperature (T) herein may use 40° C. However, the temperature value is given for a detailed description and is not limited thereto.

Equation 1 will be described herein in more detail with reference to FIG. 4.

The expected value (TEGΔL(c, T, G)) of a luminance variance of Equation 1 may be a function of color, temperature, and grayscale, and Equation 1 may be expressed as Equation 2.

$$TEG Δ L ( c , T , G ) = ( 1 \times Δ LF ) \times 100 ( \% ) \qquad Equation 2$$

Comparing Equation 1 and Equation 2, ΔLF represents a luminance change factor, and the luminance change factor (ΔLF) may include five factors. The expected value (TEGΔL(c, T, G)) of the luminance variance may be a value of indicating a degree of changing luminance as % with respect to 100% (or reference luminance).

If (e.g., when) determining temperature sensitivity, the most important factor selected from among five luminance change factors (ΔLF) may be a temperature sensitivity factor (TSF) included in Equation 3.

$$TSF = \frac{d ( \frac{Δ L ( c , T )}{Δ J ( c , T )} )}{dV ( c )} \qquad Equation 3$$

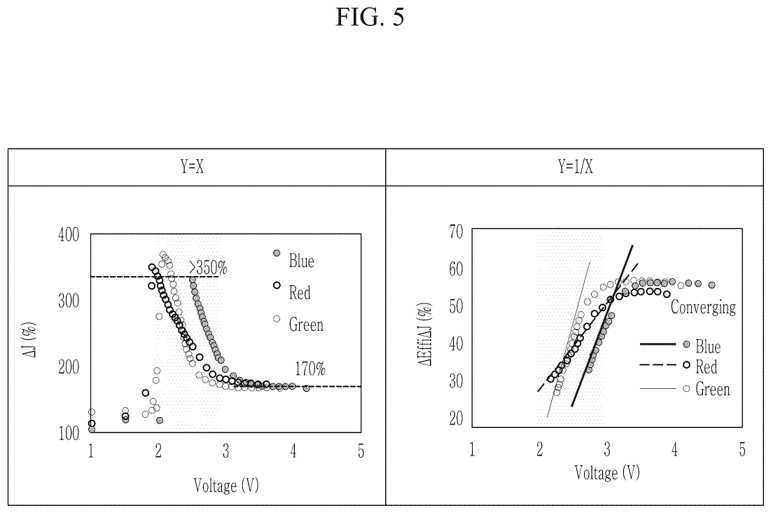

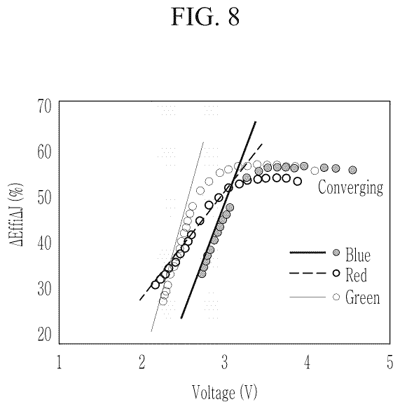

The temperature sensitivity factor (TSF) in Equation 3 represents the value considering the voltage (V), the current density (J), and the luminance (L), and it may be calculated without measuring capacitance through a separate test including a measurement value that corresponds to the first measurement group. For example, the temperature sensitivity factor (TSF) represents a slope of a tangent line in a graph of ΔL/ΔJ for the voltage (see FIG. 8), and corresponds to the slope of the tangent line at a low grayscale as the portion where the greatest temperature sensitivity is found is the low grayscale portion. A smaller value of the temperature sensitivity factor (TSF) indicates lower temperature sensitivity. A method for determining temperature sensitivity of an organic light emitting element based on the temperature sensitivity factor (TSF) of Equation 3 will be described herein in more detail with reference to FIG. 5 to FIG. 15.

The second factor and the third factor selected from among the five luminance change factors (ΔLF) are described herein in more detail.

From among the five luminance change factors (ΔLF), the second factor may correspond to a reciprocal number of the current density of the specific (e.g., set or predetermined) grayscale (G) for the current density of the reference grayscale (Go) and additionally include a constant (a) as the reciprocal number. From among the five luminance change factors (ΔLF), the third factor indicates an operating voltage value at the grayscale and/or temperature that correspond to each color.

The second factor and the third factor may have values that unrelate to temperature or may have values that are variable according to temperature, but the variable widths may not be large. As a result, if (e.g., when) considering temperature sensitivity of the organic light emitting element, the factors as described in one or more embodiments may have relatively less temperature sensitivity, compared to the temperature sensitivity factor (TSF) of Equation 3, so the second factor and the third factor may not be considered.

From among the five luminance change factors (ΔLF), the fourth factor represents the variance of the current density value, as expressed in Equation 4.

$$Δ J ( c , T , G ) = \frac{J ( c , T , G )}{J ( c , {T}_{0} , G )} \qquad Equation 4$$

According to Equation 4, the fourth factor represents a ratio of the current density that corresponds to the specific (e.g., set or predetermined) temperature (T) to the current density that corresponds to the reference temperature (T₀), with respect to substantially the same color and substantially the same grayscale.

The fourth factor may have a value variable by the temperature and may be indirectly included in Equation 3 that corresponds to the change of the current density included in Equation 3. Therefore, if (e.g., when) considering the temperature sensitivity of the organic light emitting element, and considering the temperature sensitivity factor (TSF) of Equation 3, they may not be separately considered.

From among the five luminance change factors (ΔLF), the fifth factor is the lateral leakage factor (LL) expressed in Equation 5.

$$LL = 1 - ( \frac{β \times Δ Cap ( c , T ) \times \vert Δ Op . V ( c , T , G ) \vert}{Op . V ( c , G )} ) \qquad Equation 5$$

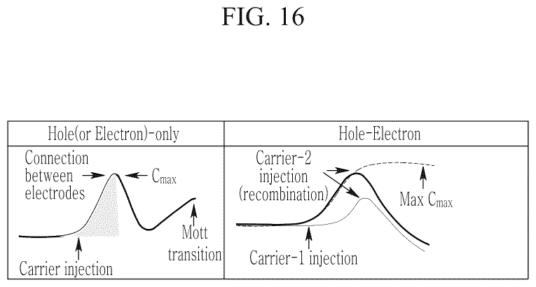

The lateral leakage factor (LL) is a value considering the capacitance (Cap) and the voltage (V), and it may be calculated without measuring the luminance (L) or the current density (J) according to performance of another test while including the measurement value that corresponds to the second measurement group. For example, the lateral leakage factor (LL) may correspond to a leakage current generated by the organic light emitting element and correspond to an amount of electrons or holes that do not move between the cathode and the anode but are leaked (see FIG. 16). The lateral leakage factor (LL) may have a larger value, which indicates greater lateral leakage and less current that flows between the cathode and the anode, so the luminance variation according to temperature (hereinafter referred to as temperature sensitivity according to the lateral leakage) may be relatively small. The lateral leakage factor (LL) of Equation 5 will be described herein in more detail with reference to FIG. 16 to FIG. 20, and a method for determining temperature sensitivity of the organic light emitting element according to the lateral leakage will be described herein in more detail based on the lateral leakage factor (LL) value.

The temperature sensitivity factor (TSF) of Equation 3 will be described herein in more detail with reference to FIG. 5 to FIG. 14.

Referring to Equation 3, the temperature sensitivity factor (TSF) may determine the temperature sensitivity of the organic light emitting element through changes in the current density (J) and the luminance (L) according to changes in the temperature (T), and it may be obtained by differentiating the luminance variance (ΔL) on the variance of current density (ΔJ) with respect to the voltage (V). Also, the temperature sensitivity factor (TSF) may refer to the slope of the tangent line on a graph (see FIG. 8, et seq.) where the x-axis is the voltage (V) and the y-axis is ΔL/ΔJ.

Referring to Equation 3, the variance of current density (ΔJ) and the luminance variance (ΔL) may be functions of the color (c) and the temperature (T), respectively, and the voltage (V) may be the function of the color (c). The current density (J) may correspond to the operating voltage (Op.V).

Also, the respective values ΔJ, ΔL, and V of Equation 3 may vary depending on the grayscale, and referring to FIG. 5 to FIG. 14, the luminance of the organic light emitting element may change significantly or substantially in the low grayscale portion depending on the temperature so the values ΔJ, ΔL, and V of Equation 3 may use the values in the low grayscale. The temperature sensitivity of the organic light emitting element may be confirmed through the temperature sensitivity factor (TSF) in the low grayscale. The low grayscale may use a set or predetermined grayscale range selected from among the grayscales that is less than the 23^{rd} grayscale that is the reference grayscale GO.

If (e.g., when) the temperature sensitivity factor (TSF) of Equation 3 increases, it may signify the changes that are sensitive to the change of temperature, so if (e.g., when) the temperature sensitivity factor (TSF) is low, the luminance and/or the color of the display device may not be changed depending on temperature, and the display quality may be improved or enhanced.

The meaning of the temperature sensitivity factor (TSF) that corresponds to Equation 3 will be described herein in more detail with reference to FIG. 5 to FIG. 14.

FIG. 5 to FIG. 14 are the meanings of expressions that correspond to temperature sensitivity of an organic light emitting element according to one or more embodiments.

FIG. 5 to FIG. 14 graphically illustrate the temperature sensitivity factor (TSF) of Equation 3 and items included therein.

FIG. 5 will be described herein in more detail.

FIG. 5 is a graph on a ratio (ΔL/ΔJ) of the variance (ΔJ) of the current density on the voltage, the variance (ΔJ) of the current density on the voltage, and the variance (ΔL) of the luminance. A test may be performed with the temperatures of 25° C. and 40° C. to check the changes with respect to temperature in FIG. 5 and below; for example, the variance (ΔJ) of current density at a specific (e.g., set or predetermined) voltage may represent a difference of current densities at 25° C. and 40° C. at a specific (e.g., set or predetermined) voltage.

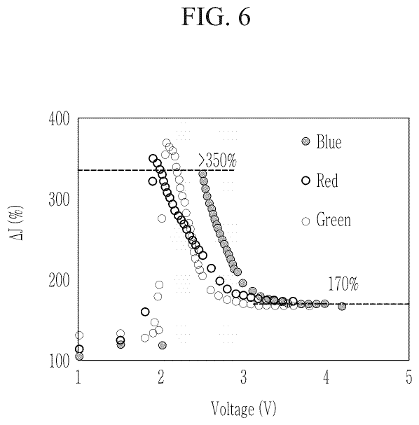

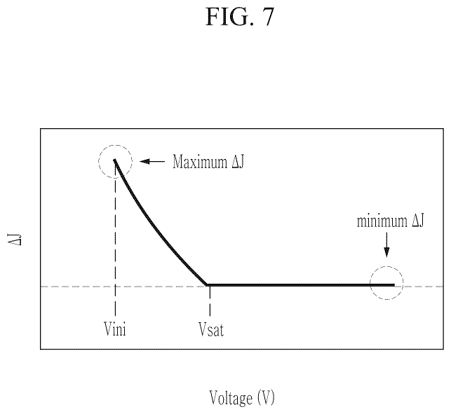

The variance (ΔJ) of current density corresponds to variance of amount of change of electrons or holes so it may correspond to the change of current that flows to the organic light emitting element. Referring to FIG. 6 and FIG. 7, the amount of change of electrons or holes increases depending on the temperature so the variance (ΔJ) of current density may be a factor to increase the temperature sensitivity factor (TSF).

If (e.g., when) the two graphs of FIG. 5 are seen with respect to the variance (ΔJ) of current density, they may have an inversely proportional relationship with each other, for example, if (e.g., when) the left graph of FIG. 5 is set as Y=X, the right graph of FIG. 5 may be indicated as Y=1/X.

The two graphs of FIG. 5 will be described herein in more detail with FIG. 5 to FIG. 14, and the left graph of FIG. 5 will be described herein in more detail with reference to FIG. 6 and FIG. 7.

FIG. 6 is the enlarged left graph of FIG. 5, and FIG. 7 is a graph on FIG. 6.

FIG. 6 is the variance (ΔJ) of the current density for the voltage for the respective colors, for example, red, green, and blue. Referring to FIG. 6, if (e.g., when) the voltage is very low, it may miss the trend line so the corresponding voltage range may not be used, the variance (ΔJ) of current density at the low voltage value (that corresponds to a low grayscale) may be relatively high, and the variance (ΔJ) of current density may be reduced as approaching to the high voltage value (or a high grayscale). The low grayscale may use a set or predetermined grayscale range selected from among the grayscales that is less than the 23^{rd} grayscale which is the reference grayscale GO.

The characteristics of FIG. 6 are shown in FIG. 7. Referring to FIG. 7, the variance (or maximum ΔJ) of maximum current density may be the variance (ΔJ) value of current density at an initial voltage (Vini) in the range of voltage applied to the organic light emitting element. The variance (or minimum ΔJ) of the minimum current density may be the variance (ΔJ) value of current density at the highest voltage in the range of voltage applied to the organic light emitting element, and it may have the variance (ΔJ) of substantially the same current density if (e.g., when) the voltage is equal to or greater than a set or predetermined voltage (hereinafter a saturation voltage (Vsat)) so it may have the variance (minimum ΔJ) of the minimum current density at the saturation voltage (Vsat).

Referring to FIG. 6, the variance (maximum ΔJ) of maximum current density at the low grayscale may have the range of 380±60%, and the variance (minimum ΔJ) of minimum current density at the high grayscale may have the range of 170±30%. The low grayscale may be equal to or less than the 23^{rd} grayscale, the high grayscale may be greater than the 23^{rd} grayscale, and the grayscale value that is the reference of the low grayscale and the high grayscale may be variable depending on one or more embodiments.

A difference (|Vsat−Vini|) between an initial voltage (Vini) that corresponds to the variance (maximum ΔJ) of maximum current density and a saturation voltage (Vsat) at a point converging to the variance (minimum ΔJ) of minimum current density may have the value of equal to or greater than 0.3 V. The initial voltage (Vini) may have the value of equal to or greater than −1 V and equal to or less than 6 V, and the saturation voltage (Vsat) may have the value of equal to or greater than 1.3 V and equal to or less than 10 V. In one or more embodiments, the entire voltage range of the operating voltage applied to the organic light emitting element may have the value of equal to or greater than −1 V and equal to or less than 10 V.

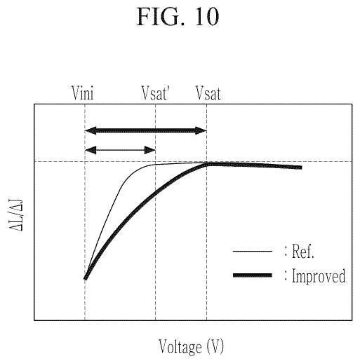

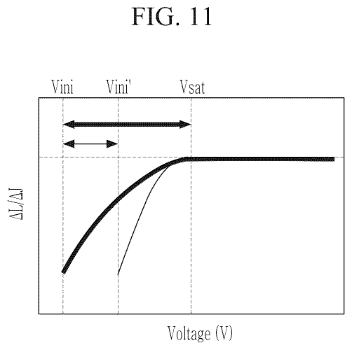

The initial voltage (Vini) may be the value of the voltage on one side in the range of the voltage applied to the organic light emitting element, and referring to FIG. 10 and FIG. 11 together with FIG. 7, the saturation voltage (Vsat) may represent the voltage at which the variance (ΔJ) of current density or the ratio (ΔL/ΔJ) of the variance (ΔJ) of current density and the variance (ΔL) of luminance starts being saturated. Referring to FIG. 7, the initial voltage (Vini) may have the lowest voltage value, but depending on one or more embodiments, the initial voltage (Vini) may have the highest voltage value so the absolute value mark is added to the difference value between the initial voltage (Vini) and the saturation voltage (Vsat).

The right graph of FIG. 5 will be described herein in more detail with reference to FIG. 8 to FIG. 14.

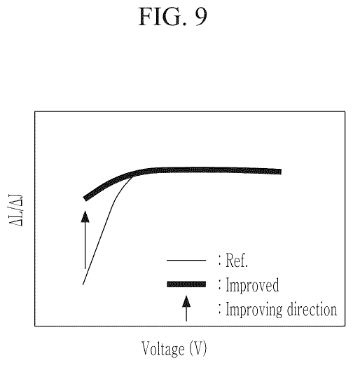

FIG. 8 is the enlarged right graph of FIG. 5, and FIG. 9 to FIG. 14 illustrate one or more embodiments to lower the temperature sensitivity factor (TSF).

FIG. 8 illustrates the ratio (ΔL/ΔJ) of the variance (ΔJ) of current density for the voltage and the variance (ΔL) of luminance for each color, for example, red, green, and blue. Referring to FIG. 8, the ratio (ΔL/ΔJ) of the variance (ΔJ) of current density and the variance (ΔL) of luminance at the low voltage value (that corresponds to the low grayscale) may be relatively small, and the ratio (ΔL/ΔJ) of the variance (ΔJ) of current density and the variance (ΔL) of luminance may increase if (e.g., when) approaching the high voltage value (or the high grayscale). The low grayscale may use a set or predetermined grayscale range selected from among the grayscales that is less than the 23^{rd} grayscale which is the reference grayscale GO.

One or more embodiments to improve or enhance the characteristics of FIG. 8 are shown in FIG. 9 to FIG. 14.

The ratio (ΔL/ΔJ) of the variance (ΔJ) of current density and the variance (ΔL) of luminance is the numerator in the temperature sensitivity factor (TSF) of Equation 3 so it may be desired or required to reduce the variance of the ratio (ΔL/ΔJ) of the variance (ΔJ) of current density and the variance (ΔL) of luminance to reduce the temperature sensitivity factor (TSF). Reducing the variance of the ratio (ΔL/ΔJ) of the variance (ΔJ) of current density and the variance (ΔL) of luminance may correspond to the reduction of the slope in the graph of FIG. 8.

For example, FIG. 8 is a graph of values obtained by dividing the variance (ΔL) of luminance by the variance (ΔJ) of current density for the respective voltages. The temperature sensitivity factor (TSF) of Equation 3 is a differentiated value of the graph of FIG. 8 and corresponds to the slope of the tangent line in the graph of FIG. 8. The slope of the tangent line is changed according to the voltage/grayscale, and a portion that is sensitive to the temperature is a low grayscale so the slopes of the tangent lines on the low grayscale portions of the respective elements are shown with dotted lines. The slope marked with the dotted lines corresponds to a size of the temperature sensitivity factor (TSF), and the lower the slope, the lower the temperature sensitivity of the corresponding element.

FIG. 9 illustrates reducing of the slope by increasing the ratio (ΔL/ΔJ) of the variance (ΔJ) of current density and the variance (ΔL) of luminance in the low grayscale region. However, the improving direction as shown in FIG. 9 may require changing the material characteristics of the layers included in the organic light emitting element, for example, conductivity (e.g., electrical conductivity) of the material must be increased by increasing or enhancing mobility or decreasing resistance (e.g., electrical resistance), or energy disorder (or energy dispersion) of the material or an interface barrier at a boundary must be reduced. Therefore, changing the characteristics as in FIG. 9 may be applied concurrently (e.g., concomitantly) as it has a difference from the direction in which changing the characteristics according to the temperature of the light emitting element is predicted based on the value measured in the present disclosure.

FIG. 10 to FIG. 14 illustrate one or more embodiments of reducing the slope of the graph in FIG. 8 by changing the initial voltage (Vini) and the saturation voltage (Vsat).

FIG. 10 illustrates one or more embodiments of decreasing the slope while changing the saturation voltage (Vsat). For example, FIG. 10 illustrates one or more embodiments of reducing the slope of the graph by increasing the voltage value to the improved saturation voltage (Vsat) from the prior saturation voltage (Vsat′), and reducing the variance of the ratio (ΔL/ΔJ) of the variance (ΔJ) of current density and the variance (ΔL) of luminance.

FIG. 10, for example, may be applied by reducing the conductivity (e.g., electrical conductivity) of the material by reducing mobility or increasing resistance (e.g., electrical resistance), or by increasing the energy disorder of the material.

FIG. 11 illustrates one or more embodiments of decreasing the slope by changing the initial voltage (Vini). For example, FIG. 11 illustrates one or more embodiments in which the slope of the graph is reduced and the variance of the ratio (ΔL/ΔJ) of the variance (ΔJ) of current density and the variance (ΔL) of luminance is reduced by lowering the voltage value to the improved initial voltage (Vini) from the prior initial voltage (Vini′).

FIG. 11 may be implemented by, for example, increasing conductivity (e.g., electrical conductivity), such as reducing a dopant injecting barrier or reducing the energy level, reducing a difference of work functions of electrons, reducing the interface barrier of a charge generating layer (CGL), an electron generating layer (Ncgl) or a hole generating layer (Pcgl), reducing doping concentration of a p-doping hole injection layer (PHIL; p-doping HIL), or further lowering an energy level of a highest occupied molecular orbital (HOMO) of the p-doping hole injection layer PHIL. The doping concentration of the p-doping hole injection layer PHIL may be equal to or greater than 0.1% and equal to or less than 5%.

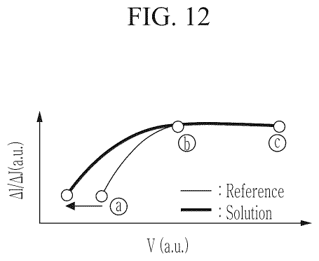

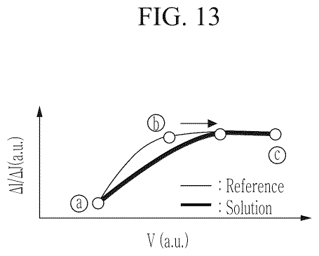

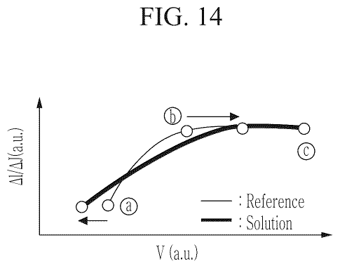

FIG. 12 to FIG. 14 illustrate one or more embodiments applied by the basic transformation of FIG. 10 and FIG. 11 and illustrate one or more embodiments of adjusting the operating voltage (Op.V). FIG. 12 illustrates lowering the operating voltage (Op.V) that corresponds to FIG. 11, FIG. 13 illustrates increasing the saturation voltage from the operating voltage (Op.V) that corresponds to FIG. 10, and FIG. 14 illustrates applying FIG. 10 and FIG. 11.

Referring to FIG. 12 to FIG. 14, \textcircled{a} indicates the ratio (ΔL/ΔJ) of the variance (ΔJ) of current density and the variance (ΔL) of luminance at the initial voltage (Vini), \textcircled{b} indicates the ratio (ΔL/ΔJ) of the variance (ΔJ) of current density and the variance (ΔL) of luminance at the saturation voltage (Vsat), and \textcircled{c} indicates the ratio (ΔL/ΔJ) of the variance (ΔJ) of current density and the variance (ΔL) of luminance at the voltage (or a final voltage) on an opposite side of the initial voltage (Vini) in the range of the voltage applied to the organic light emitting element. The initial voltage (Vini) may have the lowest voltage value and the final voltage may have the highest voltage value in the present embodiment, and they may have opposite voltage values depending on one or more embodiments.

If (e.g., when) the slope of the graph is reduced as in FIG. 12 to FIG. 14, the variance of the ratio (ΔL/ΔJ) of the variance (ΔJ) of current density and the variance (ΔL) of luminance may be reduced.

Referring to FIG. 8, the minimum value of ΔL/ΔJ at the low grayscale may have the range of 30±10%, and the maximum value of ΔL/ΔJ at the high grayscale may have the range of 55±10%. The low grayscale may be equal to or less than the 23^{rd} grayscale, the high grayscale may be greater than the 23^{rd} grayscale, and the grayscale value that is the standard for the low grayscale and the high grayscale may be variable according to embodiments.

Referring to FIG. 8, as described with reference to FIG. 6, the difference (|Vsat−Vini|) between the initial voltage (Vini) that corresponds to the variance (maximum ΔJ) of maximum current density and the saturation voltage (Vsat) of the point that converges to the variance (minimum ΔJ) of minimum current density may have the value of equal to or greater than 0.3 V. The initial voltage (Vini) may have the value of equal to or greater than −1 V and equal to or less than 6 V, and the saturation voltage (Vsat) may have the value of equal to or greater than 1.3 V and equal to or less than 10 V. In one or more embodiments, the entire voltage range of the operating voltage applied to the organic light emitting element may have the value of equal to or greater than −1 V and equal to or less than 10 V.

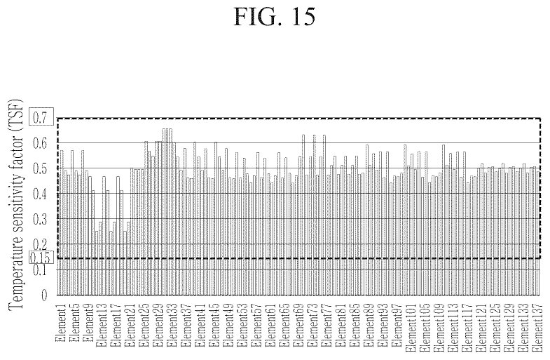

FIG. 15 is a graph of the result of measuring temperature sensitivity factors (TSF) of an organic light emitting element.

FIG. 15 is the graph of measuring temperature sensitivity factor (TSF) values of the organic light emitting elements of which luminance is not substantially changed according to the change of temperature and which are usable.

The elements used in FIG. 15 may have the range of the temperature sensitivity factor (TSF) value of equal to or greater than 0.15×10⁻¹ Cd·m²/V and equal to or less than 0.7×10⁻¹ Cd·m²/V. For example, the organic light emitting element may have the temperature sensitivity factor (TSF) value that is equal to or greater than 0.15×10⁻¹ Cd·m²/V and equal to or less than 0.25×10⁻¹ Cd·m²/V or that is equal to or greater than 0.51×10⁻¹ Cd·m²/V and equal to or less than 0.7×10⁻¹ Cd·m²/V.

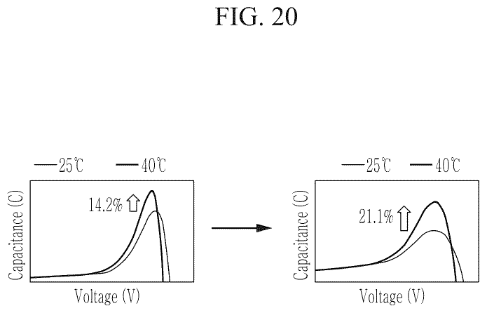

The organic layer in the organic light emitting element may have the difference between electron mobility and hole mobility that is equal to or greater than 1 e⁻⁹ cm²/Vs and equal to or less than 1 e⁻³ cm²/Vs (see FIG. 20).

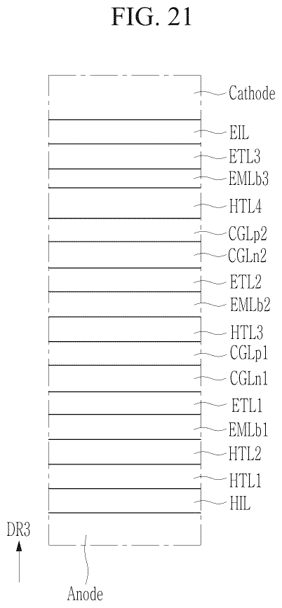

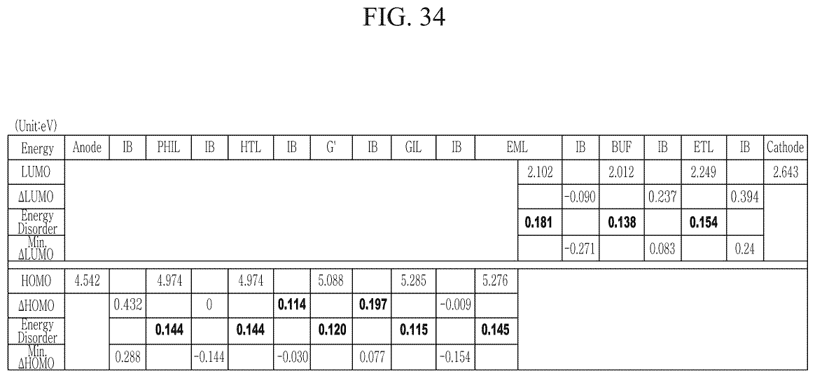

The organic light emitting element according to one or more embodiments of FIG. 5 to FIG. 15 may be an organic light emitting element in a tandem structure as shown in FIG. 21 to FIG. 26, and may satisfy the numerical range described with reference to FIG. 34.

The value that corresponds to the temperature sensitivity factor (TSF) of Equation 3 may be calculated with luminance, current density, and voltage, and may be anticipated by a J-V-L characteristic test so there may be no need to calculate capacitance by performing an additional test, and it may be beneficial or advantageous to understand the changes of luminance/colors of the organic light emitting element according to the temperature through a simple test.

The lateral leakage factor (LL) of Equation 5 will be described herein in more detail with reference to FIG. 16 to FIG. 20.

Referring to Equation 5, the lateral leakage factor (LL) may be calculated based on the operating voltage (Op.V) and the capacitance (Cap), and the factors that configure the lateral leakage factor (LL) may include three factors that exclude a constant (β). The first one of the three factors that configure the lateral leakage factor (LL) may be the variance (ΔCap(c, T)) of capacitance, and the second factor and the third factor may relate to the operating voltage and represent the variance (ΔOp.V(c, T, G)) of the operating voltage and the operating voltage (Op.V(c, G)) value.

The first factor, the variance (ΔCap(c, T)) of capacitance, may be expressed in Equation 6 if (e.g., when) described based on the maximum value.

$$Δ Cap ( c , T ) = \vert \frac{{Cap}_{max}^{′} ( c , T ) - {Cap}_{max} ( c , {T}_{0} )}{{Cap}_{max}^{′} ( c = Blue , T ) - {Cap}_{max} ( c = Blue , {T}_{0} )} \vert \times \frac{{Cap}_{max}^{′} ( c , T )}{{Cap}_{max} ( c , {T}_{0} )} \qquad Equation 6$$

Herein, Capₘₐₓ represents the maximum value in the graph of capacitance shown in FIG. 15, and Cap′ₘₐₓ is expressed in Equation 7.

$${Cap}_{max}^{′} ( c , T ) = {Cap}_{max} ( c , T ) / Δ \text{?} ( c , T ) \qquad Equation 7$$

$$\text{?} \text{indicates text missing or illegible when filed}$$

Herein, variance (ΔVₘₐₓ) of the maximum voltage is expressed in Equation 8.

$${V}_{max} ( c , T ) / {V}_{max} ( c , T ) / {V}_{max} ( c , {T}_{0} ) \qquad Equation 8$$

Herein, Vₘₐₓ represents the voltage value having the maximum value of capacitance (Capₘₐₓ) in the graph of FIG. 15, and the variance (ΔVₘₐₓ) of the maximum voltage indicates the variance of the value of Vₘₐₓ with respect to temperature.

The value of ΔCap′ₘₐₓ (hereinafter, the variance of capacitance at the maximum value) may be deduced by combining Equation 6 and Equation 7. For example, an addition of A to Equation 7 generates Equation 9, and applying the maximum value of Equation 6 to the value of ΔCapₘₐₓ of Equation 9 generates Equation 10.

$$Δ {Cap}_{max}^{′} ( c , T ) = Δ {Cap}_{max} ( c , T ) / Δ {V}_{max} ( c , T ) \qquad Equation 9$$

$$Equation 10$$

$$Δ {Cap}_{max}^{′} ( c , T ) = \vert \frac{{Cap}_{max}^{′} ( c , T ) \text{?} {Cap}_{max} ( c , {T}_{0} )}{{Cap}_{max}^{′} ( c = Blue , T ) \text{?} {Cap}_{max} ( c = Blue , {T}_{0} )} \vert \times \frac{{Cap}_{max}^{′} ( c , T )}{{Cap}_{max} ( c , {T}_{0} )} / Δ {V}_{max} ( c , T )$$

$$\text{?} \text{indicates text missing or illegible when filed}$$

The variance (ΔCap′ₘₐₓ) of capacitance at the maximum value of Equation 10 may correspond to the first factor of the lateral leakage factor (LL) and may be calculated based on the capacitance (Cap) and the voltage (V).

The variance (ΔCap′ₘₐₓ) of capacitance at the maximum value according to Equation 10 will be described herein in more detail with reference to FIG. 16 to FIG. 20.

FIG. 16 to FIG. 20 are graphs on variance of capacitance.

FIG. 16 will be described herein in more detail.

FIG. 16 illustrates the changes of capacitance according to injection of holes and/or electrons; the left graph of FIG. 16 illustrates the changes of capacitance considering only the holes and the electrons, and the right graph of FIG. 16 illustrates the changes of capacitance considering the holes and the electrons. The right graph of FIG. 16 illustrates the two lines, where a thick line indicates the change of capacitance at the high temperature 40° C. and a thin line indicates the change of capacitance at the low temperature 25° C.

Referring to the left graph of FIG. 16, if (e.g., when) the holes or electrons are injected as carriers, capacitance in the element may increase and reach the maximum capacitance (Cₘₐₓ) value before electrodes are connected to each other. The capacitance may be reduced if (e.g., when) the electrodes are connected, and the capacitance may be increased according to a Mott transition phenomenon.

However, if (e.g., when) the holes and electrons are considered as shown in the right graph of FIG. 16, the Mott transition phenomenon may not be generated, and the capacitance value may be reduced before the maximum capacitance (Cₘₐₓ) value has the maximum value (Cₘₐₓ). For example, the right graph of FIG. 16 illustrates the capacitance that changes if (e.g., when) the holes or electrons are injected as first carriers (Carrier-1), and second carriers (Carrier-2) with opposite charges to the first carriers (Carrier-1). If (e.g., when) the first carriers (Carrier-1) are injected, the capacitance may increase, and if (e.g., when) the second carriers (Carrier-2) are injected, the first carriers (Carrier-1) and the second carriers (Carrier-2) may be combined to become extinct, and the capacitance may be accordingly reduced.

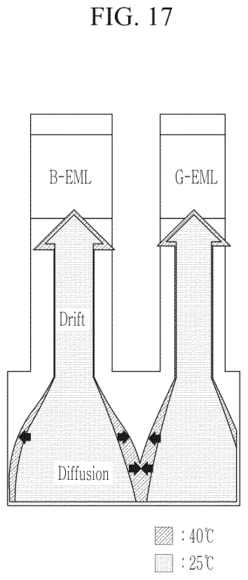

Referring to the right graph of FIG. 16, as the capacitance value is reduced by the second carriers (Carrier-2) injected before the maximum capacitance (Cₘₐₓ) value has the maximum value (Cₘₐₓ), this may correspond to the reduction in capacitance value as leakage current is generated by the light emitting element. This will be described herein in more detail with reference to FIG. 17.

FIG. 17 illustrates a portion including two light emitting layers (a blue-light emitting layer B-EML and a green-light emitting layer G-EML) selected from among the two blue- and red-light emitting elements.

Referring to FIG. 17, light may be emitted if (e.g., when) the current is applied (see Drift of FIG. 17) to the light emitting layers (the blue-light emitting layer B-EML and the green-light emitting layer G-EML), and applying the current to the light emitting layers (the blue-light emitting layer B-EML and the green-light emitting layer G-EML) may correspond to the current density of FIG. 5 as described in one or more embodiments. The injected charges may be greater than the charges applied to the light emitting layers (the blue-light emitting layer B-EML and the green-light emitting layer G-EML), one or more of which may be transmitted to a lateral surface and may be leaked (also referred to as a lateral leakage; see the horizontal arrow). In FIG. 17, the amount formed or provided to be wider in the horizontal direction at 40° C. and leaked to the lateral surface may be increased than in the case of 25° C. Therefore, the maximum capacitance (Cₘₐₓ) value may be reduced by the lateral leakage, the lateral leakage may increase if (e.g., when) the temperature increases, the current transmitted to the light emitting layers may be relatively less increased, and luminance of light emitted by the light emitting element may be reduced, so the maximum capacitance (Cₘₐₓ) value may be the factor to reduce the temperature sensitivity factor (TSF) to determine whether the luminance increases according to the temperature.

Therefore, it may be desired or required to consider the change of the maximum capacitance (Cₘₐₓ) in connection with the lateral leakage in addition to considering the increase of the variance (ΔJ) of current density by the increase of temperature, and Equation 10 may be considered in connection with the maximum capacitance (C_{maX}) value.

Equation 10 may take into account that as the temperature increases, the current or current density may increase, and the luminance may increase if (e.g., when) the temperature increases, but it may be considered to offset the increasing current or current density through the lateral leakage. For example, the energy disorder and mobility may be the proper characteristics of the light emitting element that are difficult to change, so the luminance may be controlled to change less with respect to temperature by using the value of Equation 3 or Equation 10.

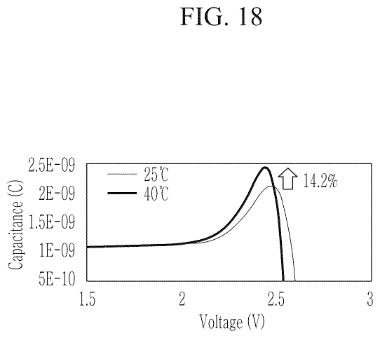

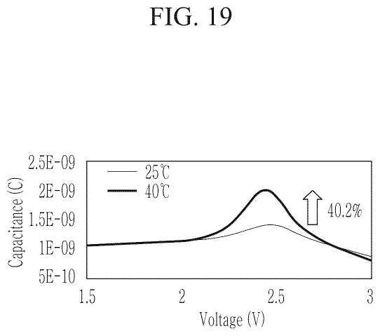

FIG. 18 and FIG. 19 illustrate how the maximum capacitance (Cₘₐₓ) changes if (e.g., when) the energy disorders of the hole transport layer HTL included in the organic light emitting element and/or the auxiliary layer between the hole transport layer HTL and the light emitting layer EML are varied, for example, a G′ layer and a GIL layer (see FIG. 34) in the green organic light emitting element.

FIG. 18 illustrates the changes of capacitance in a comparative example in which the highest occupied molecular orbital (HOMO) energy disorder of the hole transport layer HTL and the auxiliary layer has the value of less than 0.15 Ev, and FIG. 19 illustrates the changes of capacitance after the HOMO energy disorder of the hole transport layer HTL and the auxiliary layer has the value of greater than 0.15 Ev by multiplying the HOMO energy disorder of each layer of FIG. 18 by a factor of 1.25.

FIG. 18 illustrates the increase of the maximum capacitance by 14.2% at 40° C. compared to the case of 25° C., and referring to FIG. 19, it is found that the maximum capacitance is increased by 40.2% at 40° C. compared to the case of 25° C. Therefore, it may be desired or required to increase the maximum capacitance value by ensuring that the highest occupied molecular orbital (HOMO) energy disorder of the hole transport layer HTL and the auxiliary layer has the value of equal to or greater than 0.15 Ev. As a result, if (e.g., when) the lateral leakage is increased and the temperature is increased, the increase of luminance may be reduced.

For reference, the first auxiliary layer G′ and the second auxiliary layer GIL of the green organic light emitting element of FIG. 34 may be the auxiliary layers with the following characteristics. The first auxiliary layer G′ may put the electrons received on the light emitting layer EML into the light emitting layer EML and may efficiently or suitably inject the holes transmitted from the hole transport layer HTL into the light emitting layer EML, and the second auxiliary layer GIL may adjust a hole charge balance of the light emitting layer EML to increase or enhance the efficiency of the light emitting layer EML.

FIG. 20 illustrates how the maximum capacitance (Cₘₐₓ) changes by adding the auxiliary layer between the hole transport layer HTL and the light emitting layer EML.

The left graph of FIG. 20 illustrates one or more embodiments in which no auxiliary layer is between the hole transport layer HTL and the light emitting layer EML, and the right graph of FIG. 20 illustrates one or more embodiments in which a GIL layer (see FIG. 34) is added between the hole transport layer HTL and the light emitting layer EML.

Referring to the left graph of FIG. 20 without the auxiliary layer, the increase of maximum capacitance by 14.2% at 40° C. is shown compared to 25° C., but referring to the right graph of FIG. 20 in which the GIL layer is between the hole transport layer HTL and the light emitting layer EML, it is found that the maximum capacitance is increased by 21.1% at 40° C. compared to 25° C. Therefore, it is found that the maximum capacitance is increased when at least one auxiliary layer is between the hole transport layer HTL and the light emitting layer EML.

The organic layer in the organic light emitting element used in FIG. 20 may have a difference between electron mobility and hole mobility as equal to or greater than 1 e⁻⁹ cm²/Vs and equal to or less than 1 e⁻³ cm²/Vs (see FIG. 20).

As shown in FIG. 19 and FIG. 20, the increase of the maximum capacitance value may increase the lateral leakage that corresponds to the variance (ΔCap′ₘₐₓ) of capacitance at the maximum value of Equation 10 that relates to the first factor selected from among the three factors that configure the lateral leakage factor (LL).

The second factor of the lateral leakage factor (LL), the variance (ΔOp.V(c, T, G)) of the operating voltage is expressed in more detail in Equation 11.

$$Δ Op . V ( T , G ) = maximum value among ( Red - Blue ) \& ( Green - Blue ) \qquad Equation 11$$

Herein, the variance (ΔOp.V(c, T, G)) of the operating voltage represents the greater value selected from among the difference value of the operating voltages between red and blue and the difference value of the operating voltages between green and blue, and Equation 5 to find the lateral leakage factor (LL) may use the absolute value of the value of Equation 11.

The operating voltage (Op.V(c, G)), which is the third factor of the lateral leakage factor (LL), represents the operating voltage according to colors and grayscales.

The lateral leakage factor (LL) may correspond to the size of the current leaked from the organic light emitting element, and referring to Equation 5, the values of the lateral leakage factor (LL) may be changed according to the values calculated based on the first factor, the second factor, and the third factor of the lateral leakage factor (LL).

If (e.g., when) the value of the lateral leakage factor (LL) is high, the change of current that flows between the two electrodes (cathode and anode) of the organic light emitting element may be relatively reduced, and the change of luminance of the organic light emitting element may be reduced so the change of luminance with respect to temperature (hereinafter, temperature sensitivity according to lateral leakage) may be relatively small.

If (e.g., when) the value of the lateral leakage factor (LL) changes within 10% with reference to 1, it may correspond to it that the lateral leakage current may be high and the temperature sensitivity according to lateral leakage may be small.

The variance (ΔOp.V) of the operating voltage represents the difference value between the operating voltage of the organic light emitting element that displays blue and the operating voltage of the organic light emitting element that displays green and/or red. The operating voltages of green and red may use substantially the same operating voltage, and the variance (ΔOp.V) of the operating voltages may have the value of equal to or greater than 0.34 V and equal to or less than 0.54 V.

The numerical range of the variance (ΔCap′ₘₐₓ) of capacitance at the maximum value of Equation 10 that corresponds to the first factor of the lateral leakage factor (LL) may have the value of equal to or greater than 100%.

The variance (ΔCap′ₘₐₓ) value of capacitance at the maximum value of the organic light emitting element that displays green and/or red for the organic light emitting element that displays blue may be equal to or greater by a factor of 5 (or 500%). This may increase the variance of capacitance of the organic light emitting element of another color in comparison to the blue organic light emitting element having the highest operating voltage, which may be realized or provided by an increase of operating voltage, a reduction of mobility, an increase of resistance (e.g., electrical resistance), an increase of energy disorder of an organic material, or an increase or removal of the interface barrier.

According to the numerical range shown in Equation 10, the variance (ΔCap′ₘₐₓ) of capacitance at the maximum value with respect to the change of temperature may be equal to or greater than a set or predetermined level, and the lateral leakage may increase, so if (e.g., when) the temperature increases by this amount, luminance emitted by the organic light emitting element may be increased relatively less.

The variance (ΔCap) of capacitance in Equation 6 may be calculated as expressed in Equation 12.

$$Δ Cap ( c , T ) = Δ Cap ( T ) \times Δ Cap ( c ) \qquad Equation 12$$

Herein, ΔCap(T) is the variance of capacitance for each temperature, and ΔCap(c) is the variance of capacitance for each color and may have the value of Capₘₐₓ−Cgeo. Cgeo represents the capacitance value that exists if (e.g., when) there is no voltage, and the temperature may be calculated with reference to one or more temperatures, for example, it may be calculated with reference to 40° C. and 25° C.

Equation 12 and Equation 6 express the variance (ΔCap) of capacitance that is the first factor of the lateral leakage factor (LL), that simplifies the complicated Equation 6. The first factor and the second factor expressed in the variance (ΔCap) of capacitance in Equation 6 may correspond to the second factor and the first factor expressed in the variance (ΔCap) of capacitance in Equation 12.

If (e.g., when) the numerical range is satisfied, as the organic light emitting element in which the value of the lateral leakage factor (LL) satisfies the change within 10% with reference to 1, the lateral leakage value may be high, and the temperature sensitivity may be low.

The lateral leakage factor (LL) of Equation 5 considers the capacitance (Cap) and the voltage (V), and it may include a measurement value that corresponds to the second measurement group and may be calculated without measuring the luminance (L) or current density (J) according to an additional test.

The organic light emitting element according to one or more embodiments of FIG. 16 to FIG. 20 may satisfy the characteristics described with reference to FIG. 6 to FIG. 15, it may be an organic light emitting element in a tandem structure as shown in FIG. 21 to FIG. 26, and it may satisfy the numerical range as described in FIG. 34.

The organic layer of the organic light emitting element may have the difference between electron mobility and hole mobility as equal to or greater than 1 e⁻⁹ cm²/Vs and equal to or less than 1 e⁻³ cm²/Vs (see FIG. 20), and if (e.g., when) the mobility difference is high, the variance of capacitance may be increased.

One or more embodiments in which the organic light emitting element has a single light emitting layer has been described herein.

The organic light emitting element in a tandem structure including light emitting layers will be described herein in more detail.

FIG. 21 is a cross-sectional structure of the organic light emitting element in a tandem structure according to one or more embodiments.

FIG. 21 is a cross-sectional view of an organic light emitting element in a tandem structure.

FIG. 21 illustrates a first electrode (or anode) and a second electrode (or cathode) included in the organic light emitting element and illustrates three enlarged light emitting layers EMLb1, EMLb2, and EMLb3 included in the organic light emitting element and a function layer between the first electrode and the second electrode.

In FIG. 21, the light emitting element may include three light emitting layers EMLb1, EMLb2, and EMLb3; a hole injection layer HIL, a first hole transport layer HTL1, and a second hole transport layer HTL2 may be between the first electrode (or anode) and the first light emitting layer EMLb1; a first electron transport layer ETL1, a first n-charge generating layer CGLn1, a first p-charge generating layer CGLp1, and a third hole transport layer HTL3 may be between the first light emitting layer EMLb1 and the second light emitting layer EMLb2; a second electron transport layer ETL2, a second n-charge generating layer CGLn2, a second p-charge generating layer CGLp2, and a fourth hole transport layer HTL4 may be between the second light emitting layer EMLb2 and the third light emitting layer EMLb3; and a third electron transport layer ETL3 and an electron injection layer EIL may be between the third light emitting layer EMLb3 and the second electrode (or cathode).

Referring to FIG. 21, the three light emitting layers EMLb1, EMLb2, and EMLb3 and the function layer may be disconnected for each organic light emitting element, and depending on one or more embodiments, they may be connected to the light emitting layers EMLb1, EMLb2, and EMLb3 and/or the function layer of the organic light emitting element that extends to the adjacent organic light emitting element.

At least one or more of the function layers of FIG. 21 may be connected to the function layer of the adjacent organic light emitting element, and the light emitting layers EMLb1, EMLb2, and EMLb3 may not be connected to the adjacent organic light emitting element.

Referring to FIG. 21, the light emitting element may further include at least one additional light emitting layer. A charge generating layer may be further included as a function layer between the light emitting layer and the additional light emitting layer, and the charge generating layer may be between the hole transport layer and the electron transport layer.

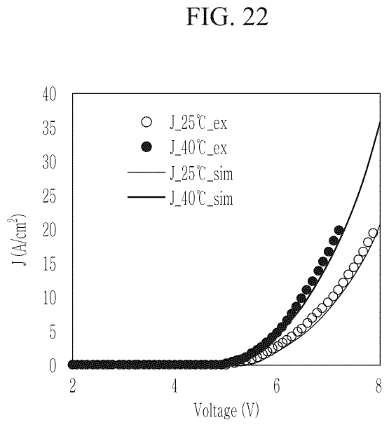

The characteristics of the organic light emitting element in a tandem structure with the cross-sectional structure shown in FIG. 21 will be described herein in more detail with reference to FIG. 22 to FIG. 26.

FIG. 22 to FIG. 26 are the graphs on characteristics of an organic light emitting element in a tandem structure.

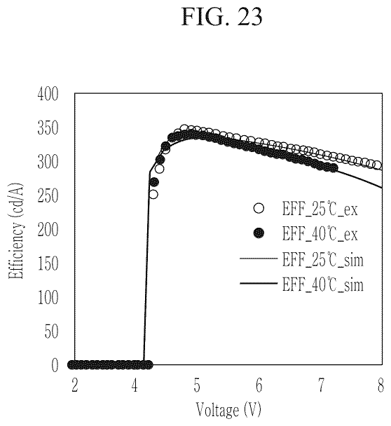

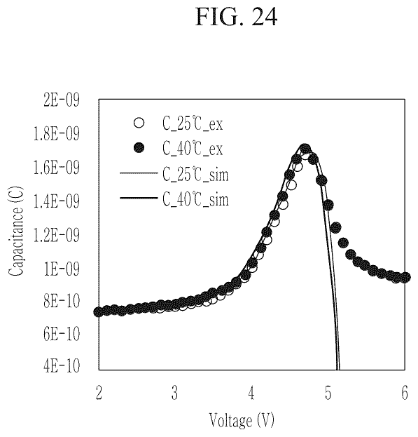

FIG. 22 to FIG. 24 illustrate one or more changes of characteristics of the organic light emitting element according to the change of temperature of the tandem structure. FIG. 22 is a graph on the current density (J), FIG. 23 is a graph on the light emitting efficiency, and FIG. 24 is a graph on the capacitance. FIG. 22 to FIG. 24 are the graphs with reference to the temperatures of 25° C. and 40° C., including direct measurement (ex) and simulated results (sim).

Referring to FIG. 22, the characteristics of the current density (J) of the organic light emitting element in a tandem structure increases as the temperature increases, and thus it may function in a similar way to the characteristics of the organic light emitting element including a single light emitting layer.

Referring to FIG. 23, the characteristics of light emitting efficiency of the organic light emitting element in a tandem structure illustrate that the light emitting efficiency quickly decreases as the temperature increases, an operation that is similar to the organic light emitting element including a light emitting layer.

Referring to FIG. 24, the characteristics of capacitance of the organic light emitting element in a tandem structure is similar to what is shown in FIG. 18 to FIG. 22, illustrating that it operates in a similar way to the organic light emitting element including a light emitting layer.

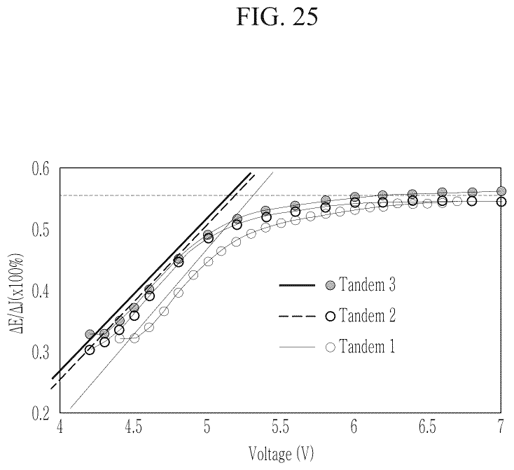

The characteristic of temperature sensitivity of the organic light emitting element in a tandem structure will be described herein in more detail with reference to FIG. 25.

As shown in FIG. 8, FIG. 25 illustrates the ratio (ΔL/ΔJ) of the variance (ΔJ) of current density for the voltage and the variance (ΔL) of luminance for red, green, and blue. In comparison to FIG. 25 and FIG. 8, it is found that their general characteristics are similar to each other while slopes have differences.

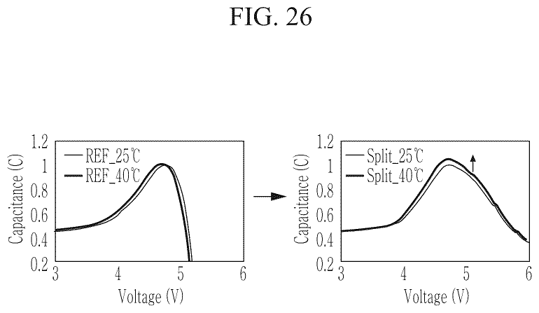

FIG. 26 illustrates how the maximum capacitance (Cₘₐₓ) of the organic light emitting element in a tandem structure changes. Similar to FIG. 20, FIG. 26 illustrates how the maximum capacitance (Cₘₐₓ) changes by distinguishing the auxiliary layer between the hole transport layer HTL and the light emitting layer EML.

The left graph of FIG. 20 illustrates a reference (REF) in which there is no auxiliary layer between the hole transport layer HTL and the light emitting layer EML, and the right graph of FIG. 20 illustrates an embodiment (Split) in which a GIL layer (see FIG. 34) is divided between the hole transport layer HTL and the light emitting layer EML.

Referring to the left graph of FIG. 20 where there is no auxiliary layer, the maximum capacitance slightly increases at 40° C. compared to 25° C., and referring to the right graph of FIG. 20 where the GIL layer is separated and provided between the hole transport layer HTL and the light emitting layer EML, it is found that the maximum capacitance is relatively substantially increased at 40° C. compared to 25° C. Therefore, it is found that the maximum capacitance of the organic light emitting element in a tandem structure may increase if (e.g., when) at least one auxiliary layer is provided between the hole transport layer HTL and the light emitting layer EML.

The organic light emitting element in a tandem structure having light emitting layers may further include a charge generating layer (CGL), and referring to FIG. 22 to FIG. 26, it may be found that the organic light emitting element of a tandem structure operates corresponding to the equation as described in one or more embodiments and the numerical range that corresponds to the organic light emitting element having a light emitting layer.

The charge generating layer (CGL) included in the tandem structure of FIG. 22 to FIG. 26 may be divided into the n-charge generating layer (CGLn) or the p-charge generating layer (CGLp), and the two charge generating layers (CGL) may have the value of equal to or greater than 0.1 Ev and equal to or less than 3.0 Ev as the interface barrier value. In one or more embodiments, n-charges (or electrons) or p-charges (or holes) may be doped to the n-charge generating layer (CGLn) or the p-charge generating layer (CGLp), and they may be doped on a boundary portion with less concentration, compared to a middle portion of the corresponding layer.

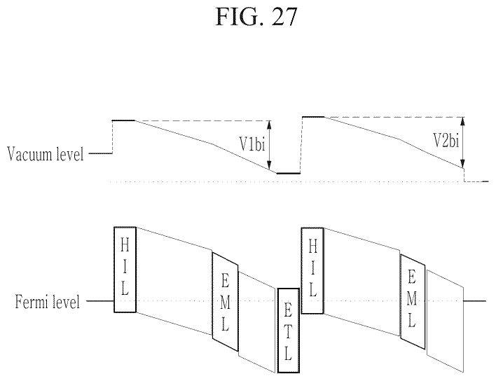

The changes of the energy levels between one or more layers in the organic light emitting element in a tandem structure will be described herein in more detail with reference to FIG. 27 to FIG. 30.

FIG. 27 to FIG. 30 illustrate energy levels of a portion of an organic light emitting element in a tandem structure according to one or more embodiments.

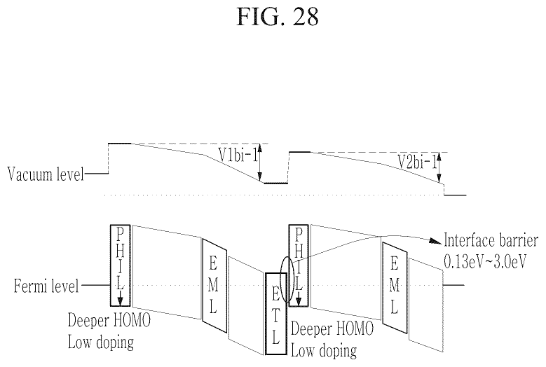

FIG. 27 illustrates the reference of the energy level in FIG. 28 to FIG. 30, and FIG. 28 to FIG. 30 illustrate the energy level changed by a modification in FIG. 27.

For example, referring to the lower part of FIG. 27, the layers among the hole injection layer HIL, the light emitting layer EML, and the electron transport layer ETL are illustrated in the organic light emitting element in a tandem structure. The upper part of FIG. 27 illustrates a lower side of the lower part of FIG. 27, illustrating the highest occupied molecular orbital (HOMO) energy level in which the holes may move. Referring to FIG. 27, the voltages that are changeable before/after one light emitting layer on the highest occupied molecular orbital (HOMO) energy level are marked as V1bi and V2bi.

Referring to FIG. 28, with respect to the organic light emitting element in a tandem structure, the hole injection layer HIL may be changed to the p-doping hole injection layer PHIL and the highest occupied molecular orbital (HOMO) energy level of the hole injection layer HIL may be lowered, which is shown as “Deeper HOMO Low doping.”

As a result, V1bi-1 and V1bi-2, the voltages changed before and after one light emitting layer on the highest occupied molecular orbital (HOMO) energy level in FIG. 28, may have voltage values that are lower than V1bi and V2bi of FIG. 27, respectively. The interface barrier between the electron transport layer ETL and the adjacent p-doping hole injection layer PHIL may have the value of equal to or greater than 0.13 Ev and equal to or less than 3.0 Ev. The doping concentration of the p-doping hole injection layer PHIL may be equal to or greater than 0.1% and equal to or less than 5%. The charge generating layer may be p-doped.

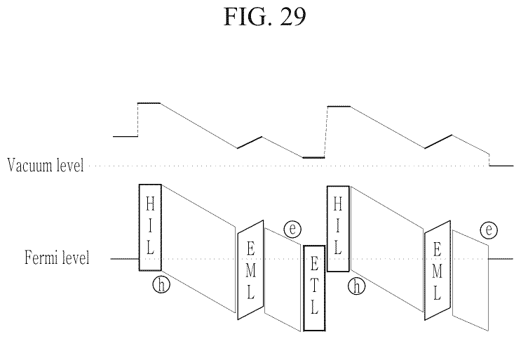

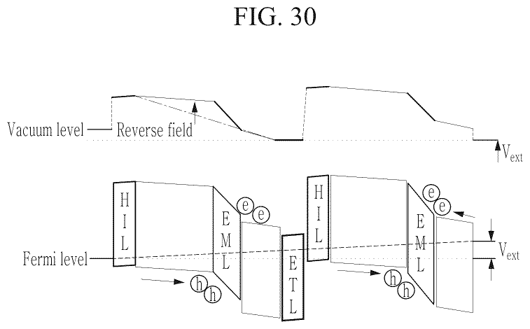

FIG. 29 and FIG. 30 illustrate additionally doped iridium (Ir), to which the hole injection layer HIL is applied, as in FIG. 27. Depending on one or more embodiments, other atoms may be doped, for example, platinum (Pt). FIG. 29 illustrates the energy level if (e.g., when) no voltage is applied from the outside, and FIG. 30 illustrates a change in energy level if (e.g., when) an external voltage is applied to the organic light emitting element in a tandem structure of FIG. 29.

FIG. 29 illustrates that the energy level of the light emitting layer EML may increase toward the right by doping, which is different from FIG. 27. FIG. 29 illustrates the holes and electrons injected by doping as \textcircled{h} and \textcircled{e}, respectively.

FIG. 30 illustrates that an external voltage may applied, and the doped electrons (\textcircled{e}) and the holes (\textcircled{h}) may move and may be gathered together on one side by an electric field. Also, a Fermi level may be changed and increased by an external voltage (Vₑₓₜ) by the electric field. By this change, the change of voltage between the hole injection layer HIL and the light emitting layer EML may be reduced by a reverse field, and the energy level of the light emitting layer EML may be reduced if (e.g., when) the direction goes to the right.

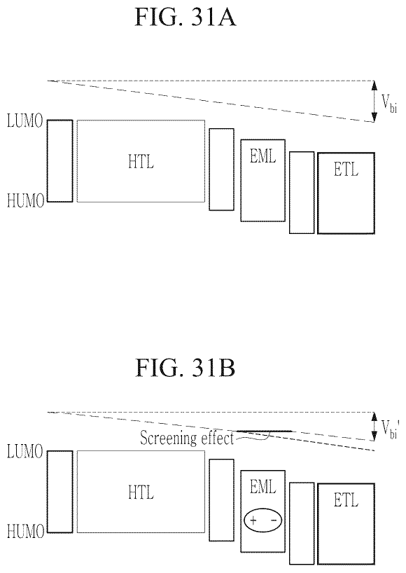

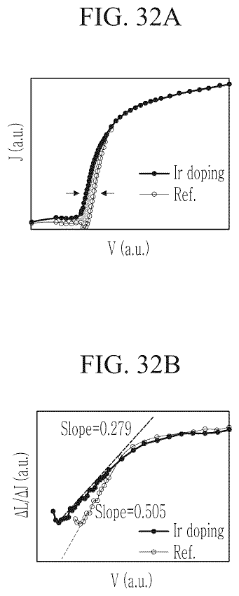

FIG. 29 and FIG. 30 illustrate that iridium (Ir) and/or platinum (Pt) may be additionally doped, and the change of energy level according to doping and temperature sensitivity will be described herein in more detail with reference to FIG. 31A, FIG. 31B, FIG. 32A, and FIG. 32B.

FIG. 31A, FIG. 31B, FIG. 32A, and FIG. 32B illustrate the graphs on changes according to an additional doping of iridium.

The added iridium (Ir) and/or platinum (Pt) may have a large molecular size and large dipole characteristics. The change of the energy level generated if (e.g., when) a dopant with a large dipole characteristic is used will be described herein in more detail with reference to FIG. 31A and FIG. 31B, and the current density with respect to voltage or the ratio (ΔL/ΔJ) of the variance of current density and the luminance variance will be described herein in more detail with reference to FIG. 32A and FIG. 32B.

The energy level will be described herein in more detail with reference to FIG. 31A and FIG. 31B.

FIG. 31A illustrates the energy level of the light emitting element to which iridium (Ir) or platinum (Pt) is not additionally doped, and FIG. 31B illustrates the energy level of the light emitting element to which iridium (Ir) or platinum (Pt) is additionally doped.

Unlike FIG. 31A, in FIG. 31B, as the material having the large dipole may be additionally doped, an additional change of energy level (or a screening effect) may be generated around the light emitting layer EML by an inductive electrode effect, and the energy level may be relatively less lowered. As a result, the difference (V_{bi}′) of the energy level of the light emitting element doped with additional iridium (Ir) or platinum (Pt) as illustrated in FIG. 31B may be reduced from the difference (V_{bi}) of the energy level of the light emitting element not doped with iridium (Ir) or platinum (Pt) as illustrated in FIG. 31A.

The current density with respect to voltage or the ratio (ΔL/ΔJ) of the variance of current density and the luminance variance will be described herein in more detail with reference to FIG. 32A and FIG. 32B.

FIG. 32A illustrates current density with respect to voltage, and FIG. 32B illustrates the ratio (ΔL/ΔJ) of the variance of current density and the luminance variance with respect to voltage. In each of the graphs, the light emitting element to which iridium (Ir) or platinum (Pt) is not additionally doped is marked as “Ref.,” and the light emitting element to which iridium (Ir) is additionally doped is marked as “Ir doping.”

Referring to FIG. 32A, it is found that if (e.g., when) iridium (Ir) is additionally doped, the current density (J) may relatively increase in the low voltage range. For example, the voltage value applied to have substantially the same current density may be lowered as an effect if (e.g., when) iridium (Ir) is additionally doped.

Referring to FIG. 32B, it is found that if (e.g., when) iridium (Ir) is additionally doped, the ratio (ΔL/ΔJ) of the variance of current density and the luminance variance may be relatively increased in the low voltage range.

As described in one or more embodiments, the temperature sensitivity factor (TSF) may correspond to the slope of the tangent line in the graph (see FIG. 8) of ΔL/ΔJ with respect to the voltage. Referring to FIG. 32B, it is found that slope value is reduced to 0.279 from 0.505 when iridium (Ir) is additionally doped. Therefore, it is found that if (e.g., when) iridium (Ir) is additionally doped, the temperature sensitivity factor (TSF) may be lowered, and the variability of the light emitting element with respect to the change of temperature may be reduced.

The change as illustrated in FIG. 31A, FIG. 31B, FIG. 32A, and FIG. 32B is also generated in the tandem structure.

The added iridium (Ir) or platinum (Pt) has a large molecular size, so it may not be relatively easy to measure according to a method that is generally available or generally used, and hence, the dipole moment values may be used to determine the degree of doping.

The dipole moment values of the light emitting elements of each color to which iridium (Ir) or platinum (Pt) is not additionally doped are given as Table 1 to Table 3, and the dipole moments have a debye unit.

TABLE 1

| Red element | Dipole moment |
|---|---|
| ETL | 0.300 |
| Buffer | 2.260 |
| REML | 0.866 and 1.589 |
| R-Dopant | 5.724 |
| RIL | 2.219 |
| HTL | 2.112 |
| HIL | 0.269 |

TABLE 2

| Green element | Dipole moment |
|---|---|
| ETL | 0.300 |
| Buffer | 2.260 |
| GEML | 2.483 and 2.875 |
| G-Dopant | 1.599 |
| GIL | 0.630 |
| G′ | 0.964 |
| HTL | 2.112 |
| PHIL | 0.269 |

TABLE 3

| Blue element | Dipole moment |
|---|---|
| ETL | 0.300 |
| Buffer | 2.260 |
| BEML | 1.114 |
| B-Dopant | 3.912 |
| BIL | 2.219 |
| HTL | 2.112 |
| PHIL | 0.269 |

The dipole moment values in Table 1 to Table 3 are values in a neutral state, an average of the dipole moment values of dopants (R-dopant, G-dopant, and B-dopant) of each color is about 3.7 debye, and the average of the dipole moment values of the entire layers that exclude the dopants (R-dopant, G-dopant, and B-dopant) is about 1.5 debye.

When iridium (Ir) or platinum (Pt) is additionally doped to the light emitting elements of each color in a neutral state, the average of the dipole moment values increases by the dipole moment value of iridium (Ir) or platinum (Pt). As a result, the average of the dipole moment values of the entire layers that exclude the dopants (R-dopant, G-dopant, and B-dopant) has the value of equal to or greater than 2 debye.

The red element expressed in Table 1, the green element expressed in Table 2, and the blue element expressed in Table 3 include one or more identical layers and include one or more different layers.

The red element of Table 1 includes a hole injection layer HIL, a hole transport layer HTL, a light emitting layer REML, a dopant R-dopant, a buffer layer, an electron transport layer ETL, and an auxiliary layer RIL. The light emitting layer REML of the red element of Table 1 is described with two hosts and two values.

The green element of Table 2 includes a p-doping hole injection layer PHIL, a hole transport layer HTL, a light emitting layer GEML, a dopant G-dopant, a buffer layer, an electron transport layer ETL, and auxiliary layers GIL and G′. The light emitting layer GEML of the green element in Table 2 is described with two hosts and two values.

The blue element of Table 3 includes a hole injection layer HIL, a hole transport layer HTL, a light emitting layer BEML, a dopant B-dopant, a buffer layer, an electron transport layer ETL, and an auxiliary layer BIL.

If (e.g., when) iridium (Ir) or platinum (Pt) is additionally doped in the organic light emitting elements of each color, iridium (Ir) or platinum (Pt) may be additionally included in each layer included in each organic light emitting element, and the dipole moments of each layer may be increased.

To sum up the organic light emitting elements of Table 1 to Table 3, the organic light emitting element may include at least two selected from among a hole injection layer HIL, a p-doping hole injection layer PHIL, a hole transport layer HTL, light emitting layers REML, GEML, and BEML, dopants R-dopant, G-dopant, and B-dopant, a buffer layer, an electron transport layer ETL, and auxiliary layers RIL, GIL, BIL, and G′, and each of the layers of the organic light emitting element may be further doped with an additional dopant, such as iridium (Ir) and/or platinum (Pt).

The average of the dipole moment values of the respective layers that exclude the dopants R-dopant, G-dopant, and B-dopant selected from among each of the layers of the organic light emitting element may be equal to or greater than 2 debye.

The average of the dipole moment values of the entire layers that exclude the dopants R-dopant, G-dopant, and B-dopant may have an improved or enhanced temperature sensitivity characteristic if (e.g., when) the average increases, so it may have no upper limit. Also, because the values in Table 1 to Table 3 are for the neutral state, there may not be an upper limit, as it may be feasible to have a large dipole moment value if (e.g., when) it is not neutral. However, the dipole moment values of the entire layers that exclude the dopants R-dopant, G-dopant, and B-dopant may have 20 debye as the upper limit value with reference to the neutral state and may have the range of equal to or greater than 2 debye and equal to or less than 20 debye.

The energy level changed by doping and applying a voltage in the organic light emitting element in a tandem structure has been described herein in more detail with reference to FIG. 27 to FIG. 30. The change of the energy level may be applied to the organic light emitting element having a light emitting layer so it may be expected that the organic light emitting element in a tandem structure and the organic light emitting element having a light emitting layer may be operated corresponding to the equation as described in one or more embodiments and the corresponding numerical ranges.

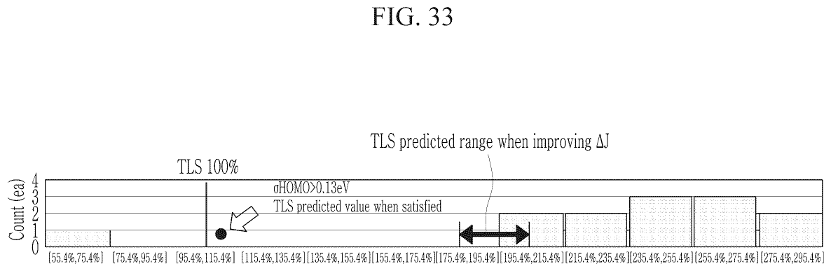

The actual measured values (TLS) of luminance variance of one or more organic light emitting elements will be described herein in more detail with reference to FIG. 33.

FIG. 33 illustrates the number of elements that corresponds to the actual measured values (TLS) of luminance variance for one or more organic light emitting elements.

For example, FIG. 33 is a graph that measures the actual measured values (TLS) of the luminance variance of one or more organic light emitting elements and counts the number of elements that belong to a set or predetermined range of the luminance variance. The luminance variance between 25° C. and 40° C. is measured at the 23^{rd} grayscale of the green organic light emitting element. In FIG. 33, 100% corresponds to a target value because there is no change of luminance with respect to change of temperature.

In FIG. 33, it is found that the luminance changes less according to the change of temperature, confirming that it may be desired or required to reduce the change of luminance according to the change of temperature.

As expressed in Equation 3, the further reduction of the change of luminance by the improvement or enhancement of the variance (ΔJ) of current density is given as the TLS prediction range at the time of improvement or enhancement of ΔJ.

An example is shown in which the actual measured value (TLS) of the luminance variance approaches 100%, and the highest occupied molecular orbital (HOMO) energy disorder (Σhomo) value is greater than 0.13 Ev. Therefore, it is found that if (e.g., when) the actual measured value (TLS) of the luminance variance is 100%, the highest occupied molecular orbital (HOMO) energy disorder (Σhomo) value may be equal to or greater than 0.13 Ev.

The characteristics of each layer of an organic light emitting element according to one or more embodiments will be described herein in more detail with reference to FIG. 34.

FIG. 34 is a table on energy levels of respective layers of an organic light emitting element according to one or more embodiments.

The organic light emitting element as illustrated in FIG. 34 is the green organic light emitting element, which includes an anode, a cathode, and a light emitting layer EML, and may further include a p-doping hole injection layer PHIL, a hole transport layer HTL, a first auxiliary layer G′, a second auxiliary layer GIL, a buffer layer BUF, and an electron transport layer ETL therebetween. Depending on one or more embodiments, the buffer layer BUF may not be provided, and the electron injection layer EIL may be further included. Herein, the first auxiliary layer G′ may be an auxiliary layer that traps the electrons having reached the light emitting layer EML in the light emitting layer EML and may efficiently or suitably inject the holes transmitted from the hole transport layer HTL into the light emitting layer EML, and the second auxiliary layer GIL may adjust the hole charge balance of the light emitting layer EML to increase or enhance the efficiency of the light emitting layer EML.

Referring to FIG. 34, an intermediate band (IB) may be included between each layer, which is additionally described to confirm the energy difference between the layers, that shows the energy value on the border of two adjacent layers.

The unit of the numbers as described in FIG. 34 is Ev, and each row as illustrated in FIG. 34 may be generally divided into two parts, and the upper part illustrates the lowest unoccupied molecular orbital (LUMO) energy level, and the lower part illustrates the highest occupied molecular orbital (HOMO) energy level. For example, the LUMO energy level additionally describes a LUMO energy difference (ΔLUMO) between adjacent layers, a LUMO energy disorder, and a LUMO energy difference (Min. ΔLUMO) of a minimum value. The highest occupied molecular orbital (HOMO) energy level additionally describes a HOMO energy difference (A HOMO) between adjacent layers, a HOMO energy disorder, and a HOMO energy difference (Min. A HOMO) of the minimum value.

Referring to FIG. 34, only the HOMO energy may exist between the light emitting layer EML and the anode, and the LUMO energy may exist between the light emitting layer EML and the cathode.

Referring to FIG. 34, the average of the interface barrier value at the border on the path on which holes are transmitted has the value of 0.152 Ev, the average calculated with reference to the minimum value has the value of 0.123 Ev, the average of the interface barrier value at the border on the path on which electrons are transmitted has the value of 0.201 Ev, and the average calculated with reference to the minimum value has the value of 0.152 Ev.

The organic light emitting element that is applicable to one or more embodiments of the present disclosure, in addition to the organic light emitting element as described in one or more embodiments, may have the following characteristics.

The interface barrier value on the border between adjacent layers may have the value between −0.3 Ev and 0.5 Ev.

The doping concentration of the p-doping hole injection layer PHIL may be equal to or greater than 0.1% and equal to or less than 5%.

In FIG. 34, there may be two auxiliary layers (e.g., the first auxiliary layer G′ and the second auxiliary layer GIL) between the hole transport layer HTL and the light emitting layer EML, but in one or more embodiments, there may be only one auxiliary layer.

In FIG. 20, the organic layer in the organic light emitting element may have the difference between electron mobility and hole mobility as equal to or greater than 1 e⁻⁹ cm²/Vs and equal to or less than 1 e⁻³ cm²/Vs.

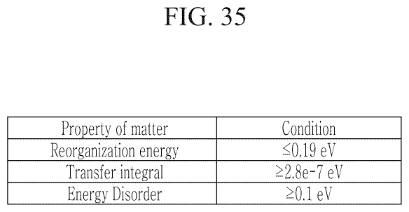

A property of the material used in the organic light emitting element will be described herein in more detail with reference to FIG. 35 to have the mobility and/or the energy gap, as described in one or more embodiments, that is lower than a set or predetermined level.

FIG. 35 is a table on conditions of an organic light emitting element according to the characteristics of the matters according to one or more embodiments.

The property of the matter of FIG. 35 describes reorganization energy, transfer integration (or a transfer matrix), and energy disorder (or energy dispersion) which are factors included in a Marcus equation based on the Marcus theory.

Referring to FIG. 35, the reorganization energy is used so that the material used in the organic light emitting element may move the electrons or holes, and the organic light emitting element may be configured or arranged by utilizing the material that has the value of equal to or less than 0.19 Ev as the reorganization energy.

Transfer integration represents the energy value by which the electrons that belong to one atom in the organic material may move to a track of another atom, and according to FIG. 35, the organic light emitting element may be configured or arranged by utilizing the material having the transfer integration value of equal to or greater than 2.8 e⁻⁷ Ev.

Energy disorder is a value to display a different degree of energy distribution with respect to a position in the material, and according to FIG. 35, the organic light emitting element may be configured or arranged by utilizing the material having the value of equal to or greater than 0.1 Ev as the energy disorder value of the organic layer in the organic light emitting element.

The organic light emitting element may be configured or arranged to have high mobility by utilizing the material that satisfies the reorganization energy, the transfer integration, and the energy disorder value as described in FIG. 35. Depending on one or more embodiments, the organic light emitting element may be configured or arranged by utilizing the material that satisfies one or more of the conditions.

Further, if (e.g., when) manufacturing the organic light emitting element, the organic light emitting element having low temperature sensitivity may be formed or provided by applying the items as described herein.

One or more embodiments of the present disclosure provide an electronic device including the display device as described in one or more embodiments.

In one or more embodiments, the electronic device may be a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IoT) device, a smartwatch, a watch phone, and/or a head-mounted display (HMD).

One or more of the numerical ranges are described without including upper or lower limits because the numerical range may be fully effective or suitable without them, and also because even if (e.g., when) there are no upper or lower limits, considering the size of the element, there is a practical upper limit because it may not be infinitely large or a practical lower limit because it must be greater than zero. Therefore, it may not be unclear even if (e.g., when) there is no upper or lower limit.

While the subject matter of the present disclosure has been described in connection with what is presently considered to be practical embodiments, it is to be understood that the present disclosure is not limited to the disclosed embodiments, but, on the contrary, is intended to cover one or more suitable modifications and equivalent arrangements included within the spirit and scope of the appended claims and equivalents thereof. It therefore will be understood that one or more embodiments described herein are just illustrative but not limitative in all aspects.

Description of Symbols/Reference Numerals

| | |
|---|---|
| 1000: display device | DA: display area |
| PA: non-display area | P: pixel |
| LED: organic light emitting element | PC: pixel driver |
| T1, T2: transistor | C1: first capacitor |
| Pad-A, Pad-C: pad | 380: pixel defining layer |
| OP: opening | Anode: anode |
| Cathode: cathode | EML: light emitting layer |
| FL, FL1, FL2: function layer | 161: first scan line |
| 171: data line | 172: first driving voltage |
| | line |
| 179: second driving voltage line | |
| TEGΔL: expected value of luminance variance | |
| TLS: actual measured value of luminance | |
| variance | |
| TSF: temperature sensitivity factor | |
| LL: lateral leakage factor | J: current density |
| L: luminance | Op. V: operating voltage |

What is claimed is:

1. A display device, comprising:
a red pixel, a green pixel, and a blue pixel, each comprising transistors and an organic light emitting element,
wherein, with respect to the organic light emitting element, variance (ΔCap′ₘₐₓ) of capacitance at a maximum value of Equation 10 has a value of equal to or greater than 100%;
$$Δ {Cap}_{usx}^{′} ( c , T ) = \vert \frac{{Cap}_{max}^{′} ( c , T ) - {Cap}_{max} ( c , {T}_{0} )}{{Cap}_{max}^{′} ( c = Blue , T ) - {Cap}_{max} ( c = Blue , {T}_{0} )} \vert \times \frac{{Cap}_{max}^{′} ( c , T )}{{Cap}_{max} ( c , {T}_{0} )} / Δ {V}_{max} ( c , T ) \qquad Equation 10$$
variable c is a color, T is a temperature, To is 25° C., Cap is capacitance, ΔCap′ₘₐₓ(c, T) satisfies Equation 9,
$$Δ {Cap}_{max}^{′} ( c , T ) = Δ {Cap}_{max} ( c , T ) / Δ {V}_{max} ( c , T ) , \qquad Equation 9$$
variance (ΔCap(c, T)) of capacitance expressed based on a maximum value satisfies Equation 6,
$$Equation 6$$
$$Δ Cap ( c , T ) = \vert \frac{{Cap}_{max}^{′} ( c , T ) - {Cap}_{max} ( c , {T}_{0} )}{{Cap}_{max}^{′} ( c = Blue , T ) - {Cap}_{max} ( c = Blue , {T}_{0} )} \vert \times \frac{{Cap}_{max}^{′} ( c , T )}{{Cap}_{max} ( c , {T}_{0} )} ,$$
and variance (ΔVₘₐₓ) of a maximum voltage satisfies Equation 8
$$Δ {V}_{max} ( c , T ) = {V}_{max} ( c , T ) / {V}_{max} ( c , {T}_{0} ) . \qquad Equation 8$$

2. The display device as claimed in claim 1, wherein:
the variance (ΔCap′ₘₐₓ) of capacitance at the maximum value has values for red and green that are equal to or greater than 500%.

3. The display device as claimed in claim 2, wherein:
an entire voltage range of a driving voltage applied to the organic light emitting element has a value of equal to or greater than −1 V and equal to or less than 10 V.

4. The display device as claimed in claim 2, wherein:
an organic layer of the organic light emitting element has a difference between electron mobility and hole mobility that is equal to or greater than 1 e⁻⁹ cm²/Vs and equal to or less than 1 e⁻³ cm²/Vs.

5. The display device as claimed in claim 2, wherein:
an interface barrier value at a border between adjacent layers in the organic light emitting element has a value of equal to or greater than −0.3 Ev and equal to or less than 0.5 Ev.

6. The display device as claimed in claim 2, wherein:
the organic light emitting element comprises a p-doping hole injection layer, and
doping concentration of the p-doping hole injection layer is equal to or greater than 0.1% and equal to or less than 5%.

7. The display device as claimed in claim 2, wherein:
the organic light emitting element comprises a hole transport layer, a light emitting layer, and at least one auxiliary layer between the hole transport layer and the light emitting layer.

8. The display device as claimed in claim 2, wherein:
the organic light emitting element has a tandem structure comprising light emitting layers and charge generating layers.

9. The display device as claimed in claim 8, wherein:
each of the charge generating layers is an n-charge generating layer or a p-charge generating layer, and
the n-charge generating layer or the p-charge generating layer has a value of equal to or greater than 0.1 Ev and equal to or less than 3.0 Ev as an interface barrier value.

10. The display device as claimed in claim 9, wherein:
a border portion of the n-charge generating layer or the p-charge generating layer is doped at a lower concentration than an intermediate portion of the n-charge generating layer or the p-charge generating layer.

11. The display device as claimed in claim 2, wherein:
an energy disorder value of an organic layer in the organic light emitting element has a value of equal to or greater than 0.1 Ev.

12. The display device as claimed in claim 1, wherein:
the organic light emitting element has a value of a temperature sensitivity factor (TSF) in Equation 3 of equal to or greater than 0.15×10⁻¹ Cd·m²/V and equal to or less than 0.7×10⁻¹ Cd·m²/V;
$$TSF = \frac{d ( \frac{Δ L ( c , T )}{Δ J ( c , T )} )}{dV ( c )} \qquad Equation 3$$
ΔJ is variance of current density, ΔL is luminance variance, V is voltage, variable c is color, and T is temperature.

13. The display device as claimed in claim 1, wherein:
the organic light emitting element is doped with a dopant of iridium or platinum.

14. The display device as claimed in claim 13, wherein:
the organic light emitting element comprises at least two layers selected from among a hole injection layer, a p-doping hole injection layer, a hole transport layer, a light emitting layer, a dopant layer, a buffer layer, an electron transport layer, and an auxiliary layer,
each of the at least two layers of the organic light emitting element is doped with the dopant of iridium or platinum, and
an average of dipole moment values of layers that exclude the dopant selected from among the each of the at least two layers of the organic light emitting element is equal to or greater than 2 debye.

15. A display device, comprising:
a red pixel, a green pixel, and a blue pixel, each comprising transistors and an organic light emitting element,
wherein, with respect to the organic light emitting element, the value of a temperature sensitivity factor (TSF) is equal to or greater than 0.15×10⁻¹ Cd·m²/V and equal to or less than 0.25×10⁻¹ Cd·m²/V or is equal to or greater than 0.51×10⁻¹ Cd·m²/V and equal to or less than 0.7×10⁻¹ Cd·m²/V as expressed by Equation 3;
$$TSF = \frac{d ( \frac{Δ L ( c , T )}{Δ J ( c , T )} )}{dV ( c )} \qquad Equation 3$$
ΔJ is variance of current density, ΔL is luminance variance, V is voltage, variable c is color, and T is temperature.

16. The display device as claimed in claim 15, wherein:
variance (maximum ΔJ) of maximum current density at a low grayscale has a range of 380±60%, and
variance (minimum ΔJ) of minimum current density at a high grayscale has a range of 170±30%.

17. The display device as claimed in claim 16, wherein:
a ratio (ΔL/ΔJ) value of variance (ΔJ) of minimum current density at the low grayscale and variance (ΔL) of luminance has a range of 30±10%, and
the ratio (ΔL/ΔJ) value of the variance (ΔJ) of maximum current density and the variance (ΔL) of luminance at the high grayscale has a range of 55±10%.

18. The display device as claimed in claim 17, wherein:
the low grayscale is equal to or less than a 23^{rd} grayscale, and the high grayscale is greater than the 23^{rd} grayscale.

19. The display device as claimed in claim 17, wherein:
a difference between a value of an initial voltage on one side in a range of voltage applied to the organic light emitting element and the variance (ΔJ) of current density or a saturation voltage at which the ratio (ΔL/ΔJ) of the variance (ΔJ) of current density and the variance (ΔL) of luminance starts being saturated is equal to or greater than 0.3 V.

20. An electronic device comprising a display device, wherein the display device comprises:
a red pixel, a green pixel, and a blue pixel, each comprising transistors and an organic light emitting element,
wherein, with respect to the organic light emitting element, variance (ΔCap′ₘₐₓ) of capacitance at a maximum value of Equation 10 has a value of equal to or greater than 100%;
$$Equation 10$$
$$Δ {Cap}_{max}^{′} ( c , T ) = \vert \frac{{Cap}_{max}^{′} ( c , T ) \text{?} {Cap}_{max} ( c , {T}_{0} )}{{Cap}_{max}^{′} ( c = Blue , T ) \text{?} {Cap}_{max} ( c = Blue , {T}_{0} )} \vert \times \frac{{Cap}_{max}^{′} ( c , T )}{{Cap}_{max} ( c , {T}_{0} )} / Δ {V}_{max} ( c , T )$$
$$\text{?} \text{indicates text missing or illegible when filed}$$
variable c is a color, T is a temperature, To is 25° C., Cap is capacitance, ΔCap′ₘₐₓ(c, T) satisfies Equation 9,
$$Δ {Cap}_{max}^{′} ( c , T ) = Δ {Cap}_{max} ( c , T ) / Δ {V}_{max} ( c , T ) , \qquad Equation 9$$
variance (ΔCap(c, T)) of capacitance expressed based on a maximum value satisfies Equation 6,
$$Equation 6$$
$$Δ Cap ( c , T ) = \vert \frac{{Cap}_{max}^{′} ( c , T ) - {Cap}_{max} ( c , {T}_{0} )}{{Cap}_{max}^{′} ( c = Blue , T ) - {Cap}_{max} ( c = Blue , {T}_{0} )} \vert \times \frac{{Cap}_{max}^{′} ( c , T )}{{Cap}_{max} ( c , {T}_{0} )} ,$$
and variance (ΔVₘₐₓ) of a maximum voltage satisfies Equation 8
$$Δ {V}_{max} ( c , T ) = {V}_{max} ( c , T ) / {V}_{max} ( c , {T}_{0} ) . \qquad Equation 8$$
